(19) United States
(12) Patent Application Publication
(10) Pub. No.: US 2026/0139364 A1
(43) Pub. Date: May 21, 2026

(54) COMPOSITION FOR TREATING SEMICONDUCTOR DEVICE, MANUFACTURING METHOD OF MODIFIED SUBSTRATE, MANUFACTURING METHOD OF LAMINATE, MANUFACTURING METHOD OF ELECTRONIC DEVICE, AND COMPOUND

(71) Applicant: FUJIFILM Corporation, Tokyo (JP)

(72) Inventors: Naoya Shimoju, Shizuoka (JP); Akihiro Hakamata, Shizuoka (JP); Katsuya Kondo, Shizuoka (JP); Kota Muramatsu, Shizuoka (JP)

(21) Appl. No.: 19/450,896

(22) Filed: Jan. 16, 2026

Related U.S. Application Data
(63) Continuation of application No. PCT/JP2024/029411, filed on Aug. 20, 2024.

(30) Foreign Application Priority Data
Aug. 23, 2023 (JP) 2023-135674

(51) Int. Cl. C23C 16/04; H10P 14/40; H10P 14/60; H10P 14/61; H10P 76/20

(52) U.S. Cl. CPC C23C 16/042; H10P 14/412; H10P 14/61; H10P 14/662; H10P 76/2041

(57) ABSTRACT

The present invention provides a composition for treating a semiconductor device, which is capable of forming a coating film having excellent ALD inhibition properties. The composition for treating a semiconductor device of the present invention contains a compound which has a specific functional group bonded or adsorbed to a substrate and has a carbon-carbon triple bond, and a solvent, in which the specific functional group is a basic functional group or an acidic functional group.

### CROSS-REFERENCE TO RELATED APPLICATIONS

This application is a Continuation of PCT International Application No. PCT/JP2024/029411 filed on Aug. 20, 2024, which claims priority under 35 U.S.C. § 119(a) to Japanese Patent Application No. 2023-135674 filed on Aug. 23, 2023. The above applications are hereby expressly incorporated by reference, in their entirety, into the present application.

### BACKGROUND OF THE INVENTION

### 1. Field of the Invention

The present invention relates to a composition for treating a semiconductor device, a manufacturing method of a modified substrate, a manufacturing method of a laminate, a manufacturing method of an electronic device, and a compound.

### 2. Description of the Related Art

With performance improvement of semiconductor devices, there is a demand for semiconductor elements which are finer and more precise. In the related art, top-down photolithography has been used for forming the semiconductor element, but it has been difficult to achieve the required accuracy due to mechanical factors, optical factors, and the like.

Therefore, as a bottom-up method for forming the semiconductor element, a method of selectively modifying a substrate has been studied in which selective adsorption of a compound to a specific material is utilized to form a film consisting of the compound on a region of the substrate formed of the specific material, and then the film is used for modifying regions of the substrate other than the region formed of the specific material.

Specifically, for example, a method has been devised in which a material which selectively adsorbs to a specific component is used for selectively forming a coating film which inhibits deposition of the material on a specific region of a surface of the substrate, and then an atomic layer deposition (ALD) treatment is performed to selectively deposit the material in a region where the coating film is not present, thereby modifying the substrate.

As the selective substrate modification method described above, JP2021-014631A discloses “surface treatment agent containing a phosphonic acid diester compound (P) represented by general formula (P-1) and an acid”, as a surface reforming agent and a surface reforming method in which, in a method for treating a surface including two or more regions, where adjacent regions of the two or more regions are made of different materials, at least one region can be selectively modified with a favorable reaction rate, and favorable contrast can be achieved between the regions made of different materials.

### SUMMARY OF THE INVENTION

The coating film used for selective modification of the substrate as described above is required to suppress an amount of material deposited on the coating film in a case where the atomic layer deposition treatment (ALD treatment) is performed on the coating film, that is, to have excellent ALD inhibition properties.

The present inventors have found that there is room for further improvement in ALD inhibition properties in a case where the coating film is formed of the composition disclosed in JP2021-014631A and the ALD treatment is performed on the coating film.

Therefore, an object of the present invention is to provide a composition for treating a semiconductor device, which is capable of forming a coating film having excellent ALD inhibition properties. Another object of the present invention is to provide a manufacturing method of a modified substrate, a manufacturing method of a laminate, a manufacturing method of an electronic device, and a compound.

As a result of conducting an extensive investigation to achieve the objects, the present inventors have found that the objects can be achieved by the following constitution.

[1] A composition for treating a semiconductor device, comprising:
a compound which has a specific functional group bonded or adsorbed to a substrate and has a carbon-carbon triple bond; and
a solvent,
in which the specific functional group is a basic functional group or an acidic functional group.

[2] The composition for treating a semiconductor device according to [1],
in which, in a case where the specific functional group is the basic functional group, an acid dissociation constant of a conjugate acid of the compound, which is obtained by adding a proton to the basic functional group, is 7.0 or more, and
in a case where the specific functional group is the acidic functional group, an acid dissociation constant of the compound when a proton is dissociated from the acidic functional group is 5.0 or less.

[3] The composition for treating a semiconductor device according to [1] or [2],
in which the basic functional group is an amino group, a hydrazine group, or a guanidine group.

[4] The composition for treating a semiconductor device according to any one of [1] to [3],
in which the basic functional group is a primary amino group, a secondary amino group, or a tertiary amino group.

[5] The composition for treating a semiconductor device according to any one of [1] to [4],
in which the basic functional group is a primary amino group.

[6] The composition for treating a semiconductor device according to any one of [1] to [5],
in which the acidic functional group is a phosphonic acid group, a sulfo group, or a carboxy group.

[7] The composition for treating a semiconductor device according to any one of [1] to [6],
in which the acidic functional group is a phosphonic acid group or a sulfo group.

[8] The composition for treating a semiconductor device according to any one of [1] to [7],
in which a molecular weight of the compound is 200 or more.

[9] The composition for treating a semiconductor device according to any one of [1] to [8],
in which the compound is a compound represented by General Formula (1) described later.

[10] The composition for treating a semiconductor device according to [9],
in which a molecular weight of the compound represented by General Formula (1) is 200 or more.

[11] The composition for treating a semiconductor device according to [9] or [10],
in which the compound represented by General Formula (1) satisfies at least one of a requirement X1 or a requirement X2,
the requirement X1: L¹ is a divalent linking group including a divalent aliphatic hydrocarbon group having 6 or more carbon atoms,
the requirement X2: Y¹ is an aliphatic hydrocarbon group having 6 or more carbon atoms, which may have a substituent.

[12] The composition for treating a semiconductor device according to any one of [9] to [11],
in which the compound represented by General Formula (1) satisfies at least one of a requirement Y¹ or a requirement Y²,
the requirement Y¹: L¹ is a divalent linking group including a divalent aromatic group which may have a substituent,
the requirement Y²: Y¹ is an aromatic group which may have a substituent.

[13] The composition for treating a semiconductor device according to any one of [9] to [12],
in which the compound represented by General Formula (1) is a compound represented by General Formula (1b) described later.

[14] The composition for treating a semiconductor device according to any one of [1] to [13],
in which a content of the compound is 5.00% by mass or less with respect to a total mass of the composition for treating a semiconductor device.

[15] The composition for treating a semiconductor device according to any one of [1] to [14],
in which the solvent includes an organic solvent and water.

[16] The composition for treating a semiconductor device according to any one of [1] to [15],
in which a total amount of the compound and the solvent is 99.90% by mass or more with respect to a total mass of the composition for treating a semiconductor device.

[17] The composition for treating a semiconductor device according to any one of [1] to [16],
in which a water contact angle of a film obtained by applying the composition for treating a semiconductor device is 60 degrees or more.

[18] A manufacturing method of a modified substrate, comprising:
a step of bringing a substrate into contact with the composition for treating a semiconductor device according to any one of [1] to [17]; and
a step of performing a heating treatment on the substrate in contact with the composition to form a coating film on the substrate.

[19] A manufacturing method of a laminate, comprising:
a step 1 of bringing a substrate having at least two types of surfaces of a first surface and a second surface, each surface being composed of a different material, into contact with the composition for treating a semiconductor device according to any one of [1] to [17] to form a first coating film on the first surface; and
a step 2 of performing an atomic layer deposition treatment on the substrate obtained in the step 1 to form a second coating film on the second surface.

[20] A manufacturing method of an electronic device, comprising:
the manufacturing method of a modified substrate according to [18].

[21] A compound represented by General Formula (2) described later.

[22] A compound represented by General Formula (3) described later.

According to the present invention, it is possible to provide a composition for treating a semiconductor device, which is capable of forming a coating film having excellent ALD inhibition properties. In addition, according to the present invention, it is possible to provide a manufacturing method of a modified substrate, a manufacturing method of a laminate, a manufacturing method of an electronic device, and a compound.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, meaning of each description in the present specification will be explained.

In the present specification, numerical ranges represented by “to” include numerical values before and after “to” as lower limit values and upper limit values.

In the present specification, “ppm” means “parts-per-million (10⁻⁶)”, “ppb” means “parts-per-billion (10⁻⁹)”, “ppt” means “parts-per-trillion (10⁻¹²)”.

In the present specification, in a case where there are two or more components corresponding to a certain component, “content” of such a component means the total content of the two or more components.

A compound described in the present specification may include a structural isomer, an optical isomer, and an isotope unless otherwise specified. In addition, one kind of structural isomer, optical isomer, and isotope may be included, or two or more kinds thereof may be included.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different from each other. The same applies to the definition of the number of substituents and the like.

In the present specification, with regard to a bonding direction of a divalent group (for example, —COO—), unless otherwise specified, in a case where Y in a compound represented by “X—Y—Z” is —COO—, the compound may be “X—O—CO—Z” or “X—CO—O—Z”.

In the present specification, pKa is a value determined by computation from a value based on a Hammett's substituent constant and the database of known literature values, using the following software package 1.

Software Package 1: Advanced Chemistry Development (ACD/Labs) Software V 8.14 for Solaris (1994-2007 ACD/Labs)

In a case where the pKa cannot be calculated by the above-described method, a value determined by a molecular orbital calculation method is adopted. As a specific method using the molecular orbital calculation method, a value obtained by using Gaussian 16 based on density functional theory (DFT) is adopted.

### [Composition for Treating Semiconductor Device]

Hereinafter, the composition for treating a semiconductor device according to the embodiment of the present invention (hereinafter, also referred to as “present composition”) will be described in detail.

The composition for treating a semiconductor device according to the embodiment of the present invention is a composition for treating a semiconductor device, containing a compound which has a specific functional group bonded or adsorbed to a substrate and has a carbon-carbon triple bond, and a solvent, in which the specific functional group is a basic functional group or an acidic functional group.

The mechanism by which the composition for treating a semiconductor device according to the embodiment of the present invention can solve the above-described problems is not necessarily clear, but the present inventors assume as follows.

The mechanism by which the effect is obtained is not limited by the following supposition. In other words, even in a case where an effect is obtained by a mechanism other than the following, it is included in the scope of the present invention.

In a case of performing the ALD treatment, since the treatment is generally performed in a high-temperature environment of several hundred degrees, a coating film which inhibits deposition of the material in the case of performing the ALD treatment preferably has excellent heat resistance.

Since the present composition contains a specific compound having a carbon-carbon triple bond in the molecule, the carbon-carbon triple bonds react with each other due to heat in the ALD process to form a firm coating film. Therefore, since the firm coating film can be formed in this way, it is presumed that, as a result, the coating film formed of the present composition is a coating film having excellent ALD inhibition properties.

Hereinafter, the fact that the present composition can form a coating film having more excellent ALD inhibition properties is also referred to as “effect of the present invention is more excellent”.

### [Specific Compound]

The present composition contains a compound having a specific functional group bonded or adsorbed to a substrate and having a carbon-carbon triple bond (hereinafter, also referred to as “specific compound”).

### <Specific Functional Group>

Specific examples of an aspect of interaction between the specific functional group and the substrate include a covalent bond, a coordinate bond, an ionic bond, a hydrogen bond, an acid-base interaction, a van der Waals bond, and a metal bond.

In a case where the coating film is formed on a metal surface A made of a metal material in the substrate by using the present composition, a coordinate bond or an ionic bond is preferable, and a coordinate bond is more preferable.

Examples of the above-described metal include a transition metal; and copper, cobalt, titanium, tantalum, tungsten, ruthenium, or molybdenum is preferable, cobalt, titanium, tantalum, tungsten, ruthenium, or molybdenum is more preferable, and cobalt, tungsten, ruthenium, or molybdenum is still more preferable.

In a case where the coating film is formed on a non-metal surface B made of a non-metal material in the substrate by using the present composition, a hydrogen bond, an acid-base interaction, or a covalent bond is preferable, and an acid-base interaction or a covalent bond is more preferable.

The substrate and the surfaces of the substrate will be described in detail later.

The specific functional group is preferably any of a group which is bonded or adsorbed to the metal surface A of the substrate (“interactive group A”) or a group which is bonded or adsorbed to the non-metal surface B of the substrate (“interactive group B”), and more preferably the interactive group A.

From the viewpoint that a denser coating film can be formed and the effect of the present invention is more excellent, the specific compound preferably has the specific functional group at a molecular terminal.

The number of the specific functional groups included in the specific compound is not particularly limited as long as it is 1 or more, but it is preferably 1 to 3, and more preferably 1.

As described above, the specific functional group is a basic functional group or an acidic functional group.

In a case where the specific functional group is a basic functional group, an acid dissociation constant of a conjugate acid of the specific compound, which is obtained by adding a proton to the basic functional group, (hereinafter also referred to as “pKa(b)”) is 7.0 or more.

For example, in a case where the specific compound is the following compound E-3, an equilibrium state for the pKa(b) is represented by the following dissociation equilibrium expression, and the pKa(b) is 8.2.

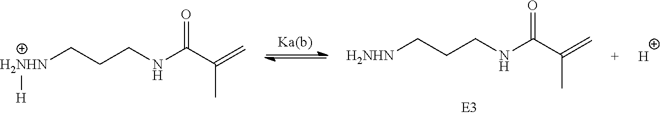

In a case where the pKa(b) is 7.0 or more, the specific functional group is easily adsorbed or bonded to the substrate (in particular, a substrate having a tungsten surface or a ruthenium surface), and a coating film exhibiting predetermined characteristics is easily and stably formed on the substrate.

The pKa(b) is preferably 8.0 or more, more preferably 9.0 or more, and still more preferably 10.0 or more. The upper limit thereof is not particularly limited, but is preferably 30.0 or less.

Examples of the basic functional group include a nitrogen-containing group.

As the nitrogen-containing group, an amino group, a hydrazine group (H₂N—NH—*; * represents a bonding position), or a guanidine group (H₂N—C(═NH)—NH—*; * represents a bonding position) is preferable; a primary amino group, a secondary amino group, or a tertiary amino group is more preferable; and a primary amino group is still more preferable.

In the present specification, an amino group included in the hydrazine group or the guanidine group is not included in the amino group (the primary amino group, the secondary amino group, or the tertiary amino group) described above. That is, the hydrazine group and the guanidine group in the present specification are regarded as groups different from the amino group.

The nitrogen-containing group may be a nitrogen-containing heterocyclic group, and examples thereof include a nitrogen-containing aromatic heterocyclic group such as a pyridyl group, an oxazolyl group, a triazine group, a pyrrole group, a pyrazole group, an imidazole group, a triazole group, a benzimidazole group, and a benzotriazole group; and nitrogen-containing aliphatic heterocyclic groups obtained by removing one hydrogen atom from an alicyclic amine such as pyrrolidine, piperidine, morpholine, 1,4-diazabicyclo[2.2.2]octane (DABCO (registered trademark)), 1,8-diazabicyclo[5.4.0]-7-undecene (DBU (registered trademark)), 7-methyl-1,5,7-triazabicyclo[4.4.0]deca-5-ene, and 1,5,7-triazabicyclo[4.4.0]deca-5-ene.

The basic functional group is preferably a group represented by any of Formulae (S1) to (S3). In Formulae (S1) to (S3), * represents a bonding position.

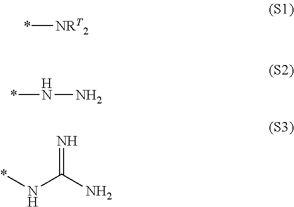

In Formula (S1), R^{T}'s each independently represent a hydrogen atom or an alkyl group (preferably having 1 to 5 carbon atoms and more preferably having 1 to 3 carbon atoms).

A plurality of R^{T}'s may be bonded to each other to form a ring. The ring to be formed is a ring including a nitrogen atom, and examples thereof include a pyridine ring, a pyrrolidine ring, a piperidine ring, and a piperazine ring.

In a case where the specific functional group is an acidic functional group, an acid dissociation constant of the specific compound when a proton is dissociated from the acidic functional group (hereinafter, also referred to as “pKa(a)”) is preferably 5.0 or less.

For example, in a case where the specific compound is the following compound E-15, an equilibrium state for the pKa(a) is represented by the following dissociation equilibrium expression, and the pKa(a) is 4.8.

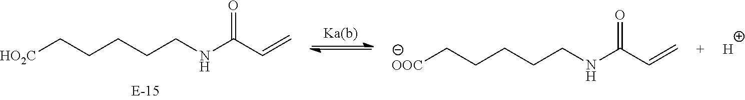

In a case where pKa(a) is 5.0 or less, the specific functional group is easily adsorbed or bonded to the substrate (in particular, a substrate having at least one of a copper surface or a cobalt surface), and a coating film exhibiting predetermined characteristics is easily and stably formed on the substrate.

The pKa(a) is preferably 10.0 or less, more preferably 5.0 or less, and still more preferably 3.0 or less. The upper limit thereof is not particularly limited, but is preferably −5.0 or more.

Examples of the acidic functional group include a phosphonic acid group (—PO₃H₂), a sulfo group (—SO₃H), a carboxy group (—COOH), a phenolic hydroxyl group, and a phosphoric acid group (—PO₄H₂). As the acidic functional group, a phosphonic acid group, a sulfo group, or a carboxy group is preferable, and a phosphonic acid group or a sulfo group is more preferable.

The above-described acidic group may form a salt in the present composition. Examples of the salt of the above-described acidic group include salts with inorganic metal ions such as an alkali metal ion and an alkaline earth metal ion.

### <Carbon-Carbon Triple Bond>

As described above, the specific compound has a carbon-carbon triple bond (hereinafter, also referred to as “C≡C bond”).

The C≡C bond is preferably a bond in which reaction between the C≡C bonds proceeds by heating.

Since the specific compound has the C≡C bond, a film containing the specific compound is formed on the substrate, and then the polymerizable groups react with each other by a heat treatment, whereby the film containing the specific compound is to be a coating film having excellent heat resistance and high inhibition properties of ALD coating film formation. In addition, since the coating film has excellent heat resistance, it is possible to widen the process window in a semiconductor device treating process.

The C≡C bond may be an intramolecular bond, or may be a C≡C bond at a molecular terminal. From the viewpoint that the effect of the present invention is more excellent, the specific compound preferably has the intramolecular carbon-carbon triple bond.

The number of C≡C bonds included in the specific compound is not particularly limited as long as it is 1 or more, but it is preferably 1 to 3, and more preferably 1 or 2.

From the viewpoint that the effect of the present invention is more excellent, a molecular weight of the specific compound is preferably 50 or more, more preferably 200 or more, and still more preferably 300 or more. The upper limit thereof is not particularly limited, and examples thereof include 1,000 or less.

### Compound Represented by General Formula (1)

As the specific compound, a compound represented by General Formula (1) is preferable.

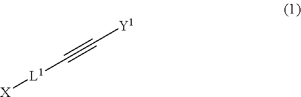

In General Formula (1),
X represents a primary amino group, a phosphonic acid group, or a sulfo group,
L¹ represents a single bond or a divalent linking group, and
Y¹ represents an aliphatic hydrocarbon group which may have a substituent, an aromatic group which may have a substituent, or a hydrogen atom.

In General Formula (1), L¹ represents a single bond or a divalent linking group.

Examples of the divalent linking group represented by L¹ include a divalent aromatic group, a divalent aliphatic hydrocarbon group, —O—, —CO— (a carbonyl group), —NR^{C}—(R^{C} represents a hydrogen atom or an alkyl group having 1 to 3 carbon atoms), and a group formed by combining two or more of these groups.

Among these, L¹ is preferably a divalent aromatic group, a divalent aliphatic hydrocarbon group, —O—, or a group formed by combining two or more of these groups. Examples of the group formed by combining two or more of the divalent aromatic group, the divalent aliphatic hydrocarbon group, and —O-include-divalent aliphatic hydrocarbon group-O-divalent aromatic group-, -divalent aliphatic hydrocarbon group-O-divalent aromatic group-O-divalent aromatic group-, and -divalent aromatic group-NH—CO-divalent aliphatic hydrocarbon group-.

The divalent aromatic group may be a divalent aromatic hydrocarbon group (arylene group) or a divalent aromatic heterocyclic group (heteroarylene group), and is preferably an arylene group.

The divalent aromatic group may be monocyclic or polycyclic.

The number of carbon atoms in the divalent aromatic group is preferably 4 to 25, more preferably 6 to 20, and still more preferably 6 to 10.

The arylene group may have a structure in which a plurality of aromatic hydrocarbon rings are bonded to each other through a single bond, such as a biphenyl structure.

Among these, as the arylene group, a group represented by any of Formulae (2-1) to (2-3) is preferable. In the formulae, * represents a bonding position.

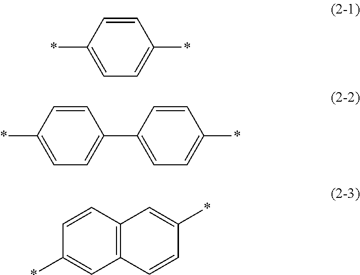

The above-described divalent aliphatic hydrocarbon group may be linear, branched, or cyclic, but is preferably linear. Examples of the divalent aliphatic hydrocarbon group include an alkylene group, an alkenylene group, and an alkynylene group; and an alkylene group or an alkynylene group is preferable.

From the viewpoint of improving stability of the film containing the specific compound on the substrate, the number of carbon atoms in the divalent aliphatic hydrocarbon group is preferably 6 to 30, more preferably 8 to 28, and still more preferably 10 to 24.

Among these, the number of carbon atoms in the alkynylene group is preferably 2 to 6, and more preferably 2 or 3.

The divalent aromatic group and the divalent aliphatic hydrocarbon group, exemplified as the divalent linking group represented by L¹, may have a substituent. The substituent is preferably an alkyl group, an alkynyl group, an alkoxy group, a phenyl group, or an amide group. The number of carbon atoms in the substituent which may be included in the divalent aromatic group and the divalent aliphatic hydrocarbon group is preferably 1 to 30, more preferably 6 to 30, still more preferably 8 to 28, and particularly preferably 10 to 24.

In General Formula (1), Y¹ represents an aliphatic hydrocarbon group which may have a substituent, an aromatic group which may have a substituent, or a hydrogen atom.

Y¹ is preferably an aliphatic hydrocarbon group which may have a substituent, or a hydrogen atom.

The aliphatic hydrocarbon group represented by Y¹ may be linear, branched, or cyclic, but is preferably linear. Examples of the aliphatic hydrocarbon group represented by Y¹ include an alkyl group, an alkenyl group, and an alkynyl group.

From the viewpoint of improving stability of the film containing the specific compound on the substrate, the number of carbon atoms in the aliphatic hydrocarbon group represented by Y¹ is preferably 6 to 30, more preferably 8 to 28, and still more preferably 10 to 24.

Examples of the substituent which may be included in the aliphatic hydrocarbon group represented by Y¹ include an aromatic group.

The aromatic group represented by Y¹ may be an aryl group or a heteroaryl group. In addition, the aromatic group represented by Y¹ may be monocyclic or polycyclic.

The number of carbon atoms in the aromatic group represented by Y¹ is preferably 4 to 25, more preferably 6 to 20, and still more preferably 6 to 10.

Examples of the substituent which may be included in the aromatic group represented by Y¹ include an alkyl group and an alkoxy group. The number of carbon atoms in the above-described alkyl group is preferably 6 to 30, more preferably 8 to 28, and still more preferably 10 to 24. The number of carbon atoms in the above-described alkoxy group is preferably 6 to 30, more preferably 8 to 28, and still more preferably 10 to 24.

The compound represented by General Formula (1) described above preferably satisfies at least one of a requirement X1 or a requirement X2.

(Requirement X1 and requirement X2)

Requirement X1: L¹ is a divalent linking group including a divalent aliphatic hydrocarbon group having 6 or more carbon atoms.

Requirement X2: Y¹ is an aliphatic hydrocarbon group having 6 or more carbon atoms, which may have a substituent.

In the above-described requirement X1, examples of the divalent aliphatic hydrocarbon group having 6 or more carbon atoms include groups having 6 or more carbon atoms among the divalent aliphatic hydrocarbon groups, which is exemplified as the divalent linking group represented by L¹. Among these, the divalent aliphatic hydrocarbon group having 6 or more carbon atoms is preferably an alkylene group having 6 or more carbon atoms.

It is sufficient that the divalent linking group including the divalent aliphatic hydrocarbon group having 6 or more carbon atoms includes the divalent aliphatic hydrocarbon group having 6 or more carbon atoms; and among these, a divalent aliphatic hydrocarbon group having 6 or more carbon atoms or -divalent aliphatic hydrocarbon group having 6 or more carbon atoms-O-divalent aromatic group- is preferable, a divalent aliphatic hydrocarbon group having 6 or more carbon atoms or -divalent aliphatic hydrocarbon group having 6 or more carbon atoms-O-phenylene group- is more preferable, and an alkylene group having 6 to 30 carbon atoms is still more preferable.

In the above-described requirement X2, examples of the aliphatic hydrocarbon group having 6 or more carbon atoms, which may have a substituent, include groups having 6 or more carbon atoms among the aliphatic hydrocarbon groups represented by Y¹, which may have a substituent.

The aliphatic hydrocarbon group having 6 or more carbon atoms, which may have a substituent, is preferably an alkyl group having 6 to 30 carbon atoms, more preferably an alkyl group having 8 to 28 carbon atoms, and still more preferably an alkyl group having 10 to 24 carbon atoms.

The compound represented by General Formula (1) described above also preferably satisfies at least one of a requirement Y¹ or a requirement Y².

(Requirement Y¹ and Requirement Y²)

Requirement Y¹: L¹ is a divalent linking group including a divalent aromatic group which may have a substituent.

Requirement Y²: Y¹ is an aromatic group which may have a substituent.

In the above-described requirement Y¹, examples of the divalent aromatic group include divalent aromatic groups exemplified as the divalent linking group represented by L¹. In addition, examples of the substituent which may be included in the divalent aromatic group include groups exemplified as the substituent which may be included in the divalent aromatic group exemplified as the divalent linking group represented by L¹.

It is sufficient that the divalent linking group including a divalent aromatic group which may have a substituent includes a divalent aromatic group which may have a substituent; and among these, an arylene group having 6 to 20 carbon atoms or -alkylene group-O-arylene group having 6 to 20 carbon atoms is preferable, and a phenylene group or -alkylene group-O-phenylene group- is more preferable.

The number of carbon atoms in the above-described alkylene group is preferably 6 to 30.

In the above-described requirement Y², the aromatic group which may have a substituent is as described for the aromatic group represented by Y¹, which may have a substituent.

### Compound Represented by General Formula (1a)

From the viewpoint that the effect of the present invention is more excellent, the above-described compound represented by General Formula (1) is preferably a compound represented by General Formula (1a).

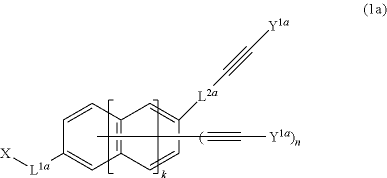

In General Formula (1a),
X represents a primary amino group, a phosphonic acid group, or a sulfo group,
L^{1a} and L^{2a} each independently represent a single bond or a divalent linking group,
Y^{1a} represents a hydrogen atom, an aliphatic hydrocarbon group which may have a substituent, or an aromatic group which may have a substituent,
k represents an integer of 0 to 2, and n represents an integer of 0 to 3, and
in a case where n is 1 or more, a plurality of Y^{1a}'s may be the same or different from each other.

In General Formula (1a), L^{1a} and L^{2a} each independently represent a single bond or a divalent linking group.

Examples of the divalent linking group represented by L^{1a} and the divalent linking group represented by L^{2a} include the groups exemplified as the divalent linking group represented by L¹ in General Formula (1) described above.

Among these, L^{1a} is preferably a divalent aliphatic hydrocarbon group, —O—, or a group formed by combining a divalent aliphatic hydrocarbon group and —O— (for example, -divalent aliphatic hydrocarbon group-O—).

Among these, L^{2a} is preferably a single bond, a divalent aliphatic hydrocarbon group, or a group formed by combining a divalent aromatic group and —O— (for example, -divalent aromatic group-O—).

The above-described divalent aliphatic hydrocarbon group may be linear, branched, or cyclic, but is preferably linear. Examples of the divalent aliphatic hydrocarbon group include an alkylene group, an alkenylene group, and an alkynylene group; and an alkylene group is preferable.

The number of carbon atoms in the divalent aliphatic hydrocarbon group is preferably 6 to 30, more preferably 8 to 28, and still more preferably 10 to 18.

The above-described divalent aliphatic hydrocarbon group may have a substituent. Examples of the substituent include a phenyl group.

In General Formula (1a), Y^{1a} represents a hydrogen atom, an aliphatic hydrocarbon group which may have a substituent, or an aromatic group which may have a substituent.

Examples of the aliphatic hydrocarbon group represented by Y^{1a}, which may have a substituent, and the aromatic group represented by Y^{1a}, which may have a substituent, include the groups exemplified as, in General Formula (1), the aliphatic hydrocarbon group represented by Y¹, which may have a substituent, and the aromatic group represented by Y¹, which may have a substituent.

Among these, Y^{1a} is preferably a hydrogen atom or an aliphatic hydrocarbon group which may have a substituent.

The above-described aliphatic hydrocarbon group may be linear, branched, or cyclic, but is preferably linear. Examples of the above-described aliphatic hydrocarbon group include an alkyl group, an alkenyl group, and an alkynyl group; and an alkyl group or an alkynyl group is preferable.

The number of carbon atoms in the above-described alkyl group is preferably 6 to 30, more preferably 8 to 28, and still more preferably 10 to 18.

The number of carbon atoms in the above-described alkynyl group is preferably 2 to 6, and more preferably 2 or 3.

The above-described aromatic group is preferably a monocyclic aryl group.

The number of carbon atoms in the above-described aromatic group is preferably 4 to 25, more preferably 6 to 20, and still more preferably 6 to 10.

The substituent which may be included in the above-described aromatic group is preferably an alkyl group, more preferably an alkyl group having 1 to 20 carbon atoms, and still more preferably an alkyl group having 1 to 18 carbon atoms.

In General Formula (1a), k represents an integer of 0 to 2, and n represents an integer of 0 to 3.

k is preferably 0 or 1, and more preferably 0. n is preferably 0 or 1.

### Compound Represented by General Formula (1b) or General Formula (1c)

The above-described compound represented by General Formula (1a) is preferably a compound represented by General Formula (1b) or a compound represented by General Formula (1c).

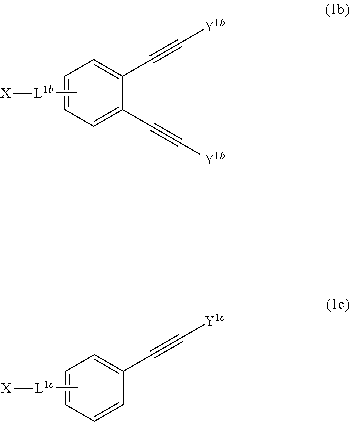

In General Formula (1b),
X represents a primary amino group, a phosphonic acid group, or a sulfo group,
L^{1b} represents a single bond or a divalent linking group, and
Y^{1b}'s each independently represent a hydrogen atom, an aliphatic hydrocarbon group which may have a substituent, or an aromatic group which may have a substituent.

In General Formula (1c),
X represents a primary amino group, a phosphonic acid group, or a sulfo group,
L^{1c} represents a single bond or a divalent linking group, and
Y^{1c} represents a hydrogen atom, an aliphatic hydrocarbon group which may have a substituent, or an aromatic group which may have a substituent.

In General Formula (1b), L^{1b} represents a single bond or a divalent linking group.

Examples of the divalent linking group represented by L^{1b} include the groups exemplified as the divalent linking group represented by L¹ in General Formula (1) described above. In addition, a suitable aspect of the divalent linking group represented by L^{1b} is the same as the suitable aspect of the divalent linking group represented by L¹.

In General Formula (1b), a bonding position between a benzene ring and L^{1b} is not particularly limited, but it is preferable that L^{1b} is bonded to a para position with respect to a position where the benzene ring and the triple bond are bonded.

In General Formula (1b), Y^{1b}'s each independently represent a hydrogen atom, an aliphatic hydrocarbon group which may have a substituent, or an aromatic group which may have a substituent.

Specific examples of the aliphatic hydrocarbon group represented by Y^{1b}, which may have a substituent, and the aromatic group represented by Y^{1b}, which may have a substituent, include the groups exemplified as, in General Formula (1), the aliphatic hydrocarbon group represented by Y¹, which may have a substituent, and the aromatic group represented by Y¹, which may have a substituent.

In General Formula (1b), it is preferable that at least one of two Y^{1b}'s is a hydrogen atom or an aliphatic hydrocarbon group which may have a substituent, and it is more preferable that both of the two Y^{1b}'s are a hydrogen atom or an aliphatic hydrocarbon group which may have a substituent.

The above-described aliphatic hydrocarbon group may be linear, branched, or cyclic, but is preferably linear. Examples of the above-described aliphatic hydrocarbon group include an alkyl group, an alkenyl group, and an alkynyl group; and an alkyl group or an alkynyl group is preferable.

The number of carbon atoms in the above-described alkyl group is preferably 6 to 30, more preferably 8 to 28, and still more preferably 10 to 18.

The number of carbon atoms in the above-described alkynyl group is preferably 2 to 6, and more preferably 2 or 3.

In General Formula (1c), L^{1c} represents a single bond or a divalent linking group.

Examples of the divalent linking group represented by L^{1c} include the groups exemplified as the divalent linking group represented by L¹ in General Formula (1) described above. In addition, a suitable aspect of the divalent linking group represented by L^{1c} is the same as the suitable aspect of the divalent linking group represented by L¹.

In General Formula (1c), a bonding position between a benzene ring and L^{1c} is not particularly limited, but is preferably bonded to a para position with respect to a position where the benzene ring and the triple bond are bonded.

In General Formula (1c), Y^{1c} represents a hydrogen atom, an aliphatic hydrocarbon group which may have a substituent, or an aromatic group which may have a substituent.

Specific examples of the aliphatic hydrocarbon group represented by Y^{1c}, which may have a substituent, and the aromatic group represented by Y^{1c}, which may have a substituent, include the groups exemplified as, in General Formula (1), the aliphatic hydrocarbon group represented by Y¹, which may have a substituent, and the aromatic group represented by Y¹, which may have a substituent.

Among these, Y^{1c} is preferably a hydrogen atom or an aliphatic hydrocarbon group which may have a substituent.

The above-described aliphatic hydrocarbon group may be linear, branched, or cyclic, but is preferably linear. Examples of the above-described aliphatic hydrocarbon group include an alkyl group, an alkenyl group, and an alkynyl group; and an alkyl group or an alkynyl group is preferable.

The number of carbon atoms in the above-described alkyl group is preferably 6 to 30, more preferably 8 to 28, and still more preferably 10 to 18.

The number of carbon atoms in the above-described alkynyl group is preferably 2 to 30, and more preferably 2 to 18.

From the viewpoint that the effect of the present invention is more excellent, a molecular weight of the above-described compound represented by General Formula (1) is preferably 50 or more, more preferably 200 or more, and still more preferably 300 or more. The upper limit thereof is not particularly limited, and examples thereof include 1,000 or less.

A content of the specific compound is preferably 0.001% to 10% by mass, more preferably 0.01% to 5.00% by mass, and still more preferably 0.01% to 0.99% by mass with respect to the total mass of the present composition.

The content of the specific polymer is preferably 80% by mass or more, more preferably 90% by mass or more, and still more preferably 93% by mass or more with respect to the total mass of all components in the present composition, excluding the solvent. The upper limit thereof is less than 100% by mass, preferably 99.9999% by mass or less.

Two or more kinds of the specific compounds may be used in combination.

In a case where two or more kinds of the specific compounds are used in combination, the total content thereof is preferably within the above-described range.

### [Solvent]

The present composition contains a solvent.

Examples of the solvent include water and an organic solvent.

The solvent preferably includes an organic solvent, and more preferably includes an organic solvent and water.

In a case where the solvent includes water and an organic solvent, a content of the organic solvent is preferably 70% by mass or more, more preferably 80.0% by mass or more, and still more preferably 90.0% by mass or more with respect to the total mass of the solvent. The upper limit thereof is less than 100% by mass, preferably 99.9% by mass or less and more preferably 99.0% by mass or less.

In a case where the solvent includes water and an organic solvent, a content of the water is preferably 0.1% by mass or more, and more preferably 1.0% by mass or more with respect to the total mass of the solvent. The upper limit thereof is preferably 30.0% by mass or less, more preferably 20.0% by mass or less, and still more preferably 10.0% by mass or less.

Examples of the above-described organic solvent include an alcohol-based solvent, an ether-based solvent, an ester-based solvent, a ketone-based solvent, an amide-based solvent, a sulfur-containing solvent, and a hydrocarbon-based solvent.

Examples of the alcohol-based solvent include a monoalcohol-based solvent, a polyol-based solvent, and a glycol monoether-based solvent.

Examples of the monoalcohol-based solvent include aliphatic monoalcohol-based solvents having 1 to 18 carbon atoms, such as methanol, ethanol (EtOH), 1-propanol, 2-propanol, 2-butanol, isobutyl alcohol, tert-butyl alcohol, isopentyl alcohol, and 4-methyl-2-pentanol (methyl isobutyl carbinol); alicyclic monoalcohol-based solvents having 3 to 18 carbon atoms, such as cyclohexanol; aromatic monoalcohol-based solvents such as benzyl alcohol; and ketone monoalcohol-based solvents such as diacetone alcohol.

Examples of the polyol-based solvent include glycol-based solvents having 2 to 18 carbon atoms, such as ethylene glycol, propylene glycol (1,2-propanediol), 1,3-propanediol, diethylene glycol, and dipropylene glycol.

Examples of the glycol monoether-based solvent include glycol monoether-based solvents having 3 to 19 carbon atoms, such as propylene glycol monomethyl ether (PGME), ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

The number of carbon atoms in the alcohol-based solvent is preferably 1 to 19, more preferably 2 to 12, and still more preferably 3 to 8.

Examples of the ether-based solvent include dialkyl ether-based solvents such as diethyl ether, dipropyl ether, diisopropyl ether, dibutyl ether, tert-butyl methyl ether, dihexyl ether, and cyclohexyl methyl ether; cyclic ether-based solvents such as tetrahydrofuran and tetrahydropyran; anisole; and diphenyl ether.

Examples of the ester-based solvent include glycol ester-based solvents; monocarboxylic acid ester-based solvents such as n-butyl acetate and ethyl lactate; lactone-based solvents such as γ-butyrolactone (GBL) and 8-valerolactone; and carbonate-based solvents such as dimethyl carbonate, diethyl carbonate, ethylene carbonate, and propylene carbonate.

Examples of the glycol ester-based solvent include glycol dicarboxylate-based solvents having 6 to 22 carbon atoms, such as ethylene glycol diacetate, diethylene glycol diacetate, triethylene glycol diacetate, tetraethylene glycol diacetate, propylene glycol diacetate, dipropylene glycol diacetate, and methoxybutyl acetate; and glycol monoether carboxylate-based solvents having 5 to 21 carbon atoms, such as propylene glycol monomethyl ether acetate (PGMEA), ethylene glycol monomethyl ether acetate, ethylene glycol monoethyl ether acetate, ethylene glycol monobutyl ether acetate, diethylene glycol monomethyl ether acetate, diethylene glycol monobutyl ether acetate, triethylene glycol monomethyl ether acetate, tetraethylene glycol monomethyl ether acetate, propylene glycol monoethyl ether acetate, propylene glycol monobutyl ether acetate, dipropylene glycol monomethyl ether acetate, tripropylene glycol monomethyl ether acetate, tetrapropylene glycol monomethyl ether acetate, and butylene glycol monomethyl ether acetate.

The number of carbon atoms in the ester-based solvent is preferably 3 to 22 and more preferably 4 to 12.

Examples of the hydrocarbon-based solvent include aliphatic hydrocarbon-based solvents such as n-pentane and n-hexane; alicyclic hydrocarbon-based solvents such as cyclohexane and methylcyclohexane; and aromatic hydrocarbon-based solvents such as toluene and xylene.

Examples of the ketone-based solvent include chain-like ketone-based solvents such as methyl isobutyl ketone, acetone, methyl ethyl ketone, diethyl ketone, methyl n-butyl ketone, 2-heptanone, ethyl n-butyl ketone, methyl n-ketone, diisobutyl ketone, and trimethylnonane; cyclic ketone-based solvents such as cyclohexanone, cyclopentanone, cycloheptanone, and methylcyclohexanone; and acetophenone.

Examples of the amide-based solvent include formamide, monomethylformamide, dimethylformamide, acetamide, monomethylacetamide, dimethylacetamide, monoethylacetamide, diethylacetamide, and N-methylpyrrolidone.

Examples of the sulfur-containing solvent include dimethyl sulfone, dimethyl sulfoxide, and sulfolane.

The solvent is preferably an alcohol-based solvent, an ether-based solvent, an ester-based solvent, ketone-based solvent; more preferably an aliphatic monoalcohol-based solvent, a glycol monoether-based solvent, a glycol ester-based solvent, a monocarboxylic acid ester-based solvent, an ether-based solvent, or a lactone-based solvent; and still more preferably a glycol monoether-based solvent or a glycol ester-based solvent.

Among these, the solvent preferably includes a glycol monoether-based solvent or an alcohol-based solvent; more preferably includes at least one selected from the group consisting of PGMEA, PGME, methyl isobutyl carbinol, isopropyl alcohol, cyclohexanone, ethyl lactate, EtOH, and γ-butyrolactone; and still more preferably includes at least one selected from the group consisting of PGMEA, PGME, methyl isobutyl carbinol, and isopropyl alcohol.

A content of the solvent is preferably 90.00% by mass or more, more preferably 95.00% by mass or more, and still more preferably 97.00% by mass or more with respect to the total mass of the present composition. The upper limit thereof is less than 100% by mass, preferably 99.999% by mass or less, more preferably 99.9% by mass or less, and still more preferably 99.0% by mass or less.

In addition, the total amount of the specific compound and the solvent is preferably 95.00% by mass or more, more preferably 99.00% by mass or more, and still more preferably 99.90% by mass or more with respect to the total mass of the present composition. The upper limit thereof is not particularly limited, and may be, for example, 100% by mass or less.

In a case where the total amount of the specific compound and the solvent is within the above-described range, an amount of components other than the specific compound and the solvent is extremely small, and as a result, the present composition contains few impurities, and the film containing the specific compound can be efficiently formed on the substrate.

Two or more kinds of the solvents may be used in combination.

In a case where two or more kinds of the solvents are used in combination, the total content thereof is preferably within the range.

### [Polymerization Inhibitor]

From the viewpoint of improving the stability of the present composition, it is preferable that the present composition contains a polymerization inhibitor.

The polymerization inhibitor is not particularly limited, and a known polymerization inhibitor can be selected, but a radical polymerization inhibitor is preferable.

The polymerization inhibitor preferably includes at least one compound selected from the group consisting of a phenol-based compound, a quinone-based compound, a free radical-based compound, an amine-based compound, and a phosphine-based compound; and from the viewpoint of polymerization inhibitory ability, a free radical-based compound is more preferable.

Examples of the phenol-based compound include 4-methoxyphenol, hydroquinone, 2-tert-butylhydroquinone, 4-tert-butylcatechol, pentaerythritol tetrakis[3-(3,5-di-tert-butyl-4-hydroxyphenyl)propionate], 2,5-di-tert-butyl-4-methylphenol, 2,6-di-tert-butyl-4-methylphenol, 4,4′-thiobis(3-methyl-6-t-butylphenol), 2,2′-methylenebis(4-methyl-6-t-butylphenol), 4-methoxynaphthol, 2,4-bis(octylthiomethyl)-6-methylphenol, p-nitrosophenol, and α-nitroso-β-naphthol.

Examples of the quinone-based compound include 1,4-benzoquinone, 1,2-benzoquinone, and 1,4-naphthoquinone.

Examples of the free radical-based compound include poly(4-methacryloyloxy-2,2,6,6-tetramethylpiperidin-N-oxyl), 4-hydroxy-2,2,6,6-tetramethylpiperidine 1-oxyl, 2,2,6,6-tetramethylpiperidine 1-oxyl, 2,2-diphenyl-1-picrylhydrazyl, and triphenylpheldazyl.

Examples of the amine-based compound include p-phenylenediamine, 4-aminodiphenylamine, N, N-diethylhydroxylamine, N,N′-diphenyl-p-phenylenediamine, N-isopropyl-N′-phenyl-p-phenylenediamine, N-(1,3-dimethylbutyl)-N′-phenyl-p-phenylenediamine, N,N′-di-2-naphthyl-p-phenylenediamine, diphenylamine, N-phenyl-β-naphthylamine, 4,4′-dicumyl-diphenylamine, 4,4′-dioctyl-diphenylamine, phenothiazine, 2-methoxyphenothiazine, phenoxazine, N-nitrosodiphenylamine, N-nitrosophenylnaphthylamine, N-nitrosodinaphthylamine, p-nitrosodiphenylamine, N-nitroso-N-phenylhydroxylamine, N-nitroso-N-phenylhydroxylamine aluminum, and cupferron. Each of the compounds exemplified as the amine-based compound may form a metal salt or a metal complex.

Examples of the phosphine-based compound include tris(2,4-di-tert-butylphenyl) phosphite.

In addition, as the polymerization inhibitor, nitrobenzene compounds such as nitrobenzene and 4-nitrotoluene or thiol ethers such as dioctadecyl 3,3′-thiodipropionate, dilauryl thiodipropionate, dimyristyl thiodipropionate, and distearyl thiodipropionate may be contained.

A molecular weight of the polymerization inhibitor is preferably 1,000 or less, more preferably 800 or less, and still more preferably 500 or less. The lower limit of the above-described molecular weight is not particularly limited, but is preferably 80 or more.

A content of the polymerization inhibitor is preferably 0.0001 parts by mass or more, more preferably 0.001 parts by mass or more, still more preferably 0.005 parts by mass or more, and particularly preferably 0.010 parts by mass or more with respect to 100 parts by mass of the content of the specific compound.

In addition, the content of the polymerization inhibitor is preferably 10.0 parts by mass or less, more preferably 1.000 part by mass or less, and still more preferably 0.100 parts by mass or less with respect to 100 parts by mass of the content of the specific compound.

The present composition may contain one kind of the polymerization inhibitor alone, or may contain two or more kinds thereof. In a case of containing two or more kinds of the polymerization inhibitors, it is preferable that the total amount thereof is within the above-described range.

### [Production Method of Present Composition]

A production method of the present composition is not particularly limited, and the present composition can be produced, for example, by mixing the above-described respective components.

An order or timing of mixing the respective components in the composition is not particularly limited. Examples thereof include a method of producing the composition by adding the specific compound to a stirrer such as a mixing mixer, into which a purified solvent has been incorporated, and then sufficiently stirring the mixture.

In a case where the composition contains other components in addition to the specific compound, the other components may be added at the same time as the specific compound or may be added at different timings.

In the production process of producing the composition, steps described below may be performed.

### (Metal Removal Step)

In the above-described production method, a metal removal step of removing a metal component from the above-described components and/or the composition (hereinafter, also called “substance to be purified”) may be performed.

### (Filtration Step)

It is preferable that the above-described production method includes a filtration step of filtering the liquid in order to remove foreign substances, coarse particles, and the like from the liquid.

The filtration method is not particularly limited, and a well-known filtration method can be used. Among these, filtering using a filter is preferable.

### (Static Charge Removal Step)

The production method of the composition may further include a static charge removal step of statically neutralizing the composition.

### [Applications of Present Composition]

The present composition is a composition for treating a semiconductor device, and is preferably used for a modification treatment of a substrate in the manufacturing process of a semiconductor device. By the above-described treatment, a modified substrate in which a coating film is formed on a surface of the substrate is obtained.

In addition, the present composition is also preferably used for manufacturing a laminate in which a material is deposited in a region where a coating film is not formed by the above-described treatment, by subjecting the above-described modified substrate to the ALD treatment.

The manufacturing method of a modified substrate and the manufacturing method of a laminate will be described in more detail later.

### <Substrate>

The substrate is not particularly limited, but preferably has at least two surfaces of a first surface and a second surface, each surface being composed of different materials. In a case of having the two surfaces, it is possible to form a coating film having high inhibition properties of an ALD coating film on one surface by selectively bonding or adsorbing a specific compound to one surface.

The above-described first surface is a surface which adsorbs or bonds to the specific functional group. It is sufficient that the above-described second surface is composed of a material different from that of the first surface, and it is preferably a surface on which a coating film is not formed in a case of being brought into contact with the present composition.

Among these, it is preferable that at least one of the first surface or the second surface is a metal surface A made of a metal material (a material including a metal atom) or a non-metal surface B made of a non-metal material, and it is more preferable that at least one of the first surface or the second surface is the metal surface A.

A metal atom contained in the metal surface A is not particularly limited, but is preferably a tungsten atom, a copper atom, a ruthenium atom, a cobalt atom, a titanium atom, a tantalum atom, a molybdenum atom, a germanium atom, a zirconium atom, an aluminum atom, a tin atom, a nickel atom, a palladium atom, an indium atom, a zinc atom, a gold atom, a silver atom, or a platinum atom, more preferably a tungsten atom, a ruthenium atom, a tantalum atom, a copper atom, or a cobalt atom, and still more preferably a tungsten atom or a copper atom.

A form of the metal atom in the metal surface A is not particularly limited, and examples thereof include a single-component metal, an alloy, a nitride, an oxide, and a silicide; and a single-component metal or an alloy is preferable. The alloy may be, for example, an alloy containing two or more types of metal atoms contained in the metal surface A described above. In a case where the first surface is the metal surface A containing a molybdenum atom, the specific functional group included in the specific compound is preferably the basic functional group.

A method of forming the metal surface A is not particularly limited, and a known method can be used. Examples thereof include a CVD method, plating, and a physical vapor deposition method.

The non-metal material constituting the non-metal surface B may be, for example, an insulator, and examples thereof include a single component non-metal such as silicon and carbon, a non-metal oxide such as a silicon oxide, a non-metal nitride such as a silicon nitride, a non-metal oxynitride such as a silicon oxynitride, and an organic substance.

The material constituting the non-metal surface B is preferably a non-metal material containing a silicon atom, and more preferably a silicon oxide.

Specific examples of the silicon oxide include a material represented by the composition of SiO_{y} (y preferably represents 0.5 to 2.0 and more preferably represents 1.0 to 2.0) and a material represented by the composition of SiO_{z}C_{w} (z preferably represents 0.5 to 2.0 and more preferably represents 1.0 to 2.0, and w preferably represents 0.5 to 2.0 and more preferably represents 1.0 to 2.0). The material represented by the composition of SiO_{y} and the material represented by the composition of SiO_{z}C_{w} may further contain hydrogen. Examples of the material represented by the composition of SiO_{z}C_{w} include Si(OC₂H₅)₄ (tetraethyl orthosilicate, TEOS). The silicon oxide is preferably a material represented by the composition of SiO₂ (silicon dioxide) or TEOS.

A method of forming the non-metal surface B is not particularly limited, and examples thereof include a CVD method, a physical vapor deposition method, plasma irradiation, and application of a precursor compound.

It is also preferable that the above-described non-metal surface B is a surface in which a region consisting of the silicon oxide has been subjected to a surface treatment. Examples of the above-described treatment include a treatment in which the surface is brought into contact with a treatment liquid such as an aqueous solution containing an acidic compound (preferably, hydrofluoric acid water), a plasma treatment, a corona treatment, and an ozone treatment.

Examples of a preferred aspect of the substrate include an aspect 1 in which the first surface is the metal surface A.

In the aspect 1, the metal atom in the metal surface A as the first surface is preferably contained in a form of a single-component metal, an alloy, a conductive metal nitride, or a metal silicide, and more preferably in a form of a single-component metal or an alloy.

Examples of the single-component metal and the alloy described above include single components of the metals exemplified as the metal contained in the metal surface A, and alloys thereof.

Examples of the above-described conductive metal nitride include tantalum nitride, titanium nitride, iron nitride, and aluminum nitride.

Examples of the above-described metal silicide include iron silicide, molybdenum silicide, and tungsten silicide.

In the aspect 1, the second surface is preferably the metal surface A different from the first surface or the non-metal surface B, and more preferably the non-metal surface B.

In the aspect 1, the metal atom in the metal surface A constituting the second surface is preferably contained in a form of a metal oxide, a metal nitride, or a metal oxynitride, and more preferably in a form of a metal oxide.

Examples of the metal oxide include aluminum oxide, tantalum oxide, iron oxide, and copper oxide.

Examples of a preferred aspect of the substrate also include an aspect 2 in which the first surface is the non-metal surface B. In the aspect 2, an interactive group included in the specific polymer is the above-described interactive group B.

In the aspect 2, the second surface is preferably the metal surface A.

In the aspect 2, the metal atom in the metal surface A as the second surface is preferably contained in a form of a single-component metal, an alloy, a conductive metal nitride, or a metal silicide, and more preferably in a form of a single-component metal or an alloy.

Shapes of the first surface and the second surface are not particularly limited, and examples thereof include a planar shape, a dotted shape, and a striped shape.

A shape of the substrate is not particularly limited, and any shape of a substrate generally used as the semiconductor substrate can be adopted. In addition, the substrate may be any substrate having the above-described surface, and may have a single layer structure or a multilayer structure.

### <Coating Film>

It is preferable that the coating film formed on the substrate by the present composition functions as a mask in a case of depositing the material in the ALD treatment. That is, in a case where the ALD treatment is performed on a modified substrate on which a coating film is formed by the present composition on a specific region, it is preferable that the material is not deposited in the region where the coating film is formed, and the material is deposited in the region where the coating film is not formed, thereby forming a film (hereinafter, also referred to as “ALD film”). As a result, a laminate in which the ALD film is selectively formed in a region other than the region where the coating film is formed is obtained.

The above-described coating film also preferably functions as a mask in a case of forming a metal-containing film by chemical vapor deposition (CVD) other than ALD. That is, in the CVD treatment, deposition of a film by CVD (hereinafter, also referred to as “CVD film”) can be suppressed in the region where the above-described coating film is formed, and the CVD film can be deposited in the region where the coating film is not formed. As a result, a laminate in which the CVD film is selectively formed in a region other than the region where the coating film is formed is obtained.

Examples of CVD other than ALD, which can be preferably applied to the above-described modified substrate, include known methods such as a thermal CVD method and a plasma CVD method. As a raw material of the CVD film used in the CVD treatment, a raw material of the ALD film, which will be described later, can be used.

A water contact angle of the film obtained by applying the present composition is preferably 60 degrees or more, more preferably 70 degrees or more, and still more preferably 80 degrees or more. The upper limit thereof is not particularly limited, and is usually 120 degrees or less.

The above-described water contact angle is a value obtained by measuring values of contact angles 500 milliseconds after a liquid droplet of water comes into contact with the surface of a measurement object three times using a contact angle meter (DMs-501, manufactured by Kyowa Interface Science Co., Ltd.), and taking an average value of the measured values.

### [Manufacturing Method of Modified Substrate]

The manufacturing method of a modified substrate according to the embodiment of the present invention includes a step of bringing the substrate into contact with the present composition, and a step of performing a heating treatment on the substrate in contact with the present composition to form a coating film on the substrate. As a result, a modified substrate in which the coating film is formed on the substrate is obtained.

A method of bringing the substrate into contact with the present composition is not particularly limited, and any known method can be used. Examples of the method of bringing the substrate into contact with the present composition include a method of applying (for example, spin coating) or spraying the present composition onto the substrate and a method of immersing the substrate in the present composition. In a case where the substrate is immersed in the present composition, the present composition may be allowed to be convected.

A temperature of the present composition in a case where the substrate is brought into contact with the present composition is not particularly limited, and is preferably 0° C. to 50° C. and more preferably 10° C. to 30° C.

After bringing the substrate into contact with the present composition, the heating treatment is performed on the substrate in contact with the present composition, whereby reaction between the triple bonds in the specific compounds is promoted.

A heating method is not particularly limited, and a known method can be used. Examples thereof include a method of bringing the present composition into contact with a heat source (for example, heating using an oven or a hot plate) and a method of irradiating the present composition with infrared rays.

The heating temperature is preferably 50° C. to 400° C., more preferably 100° C. to 350° C., still more preferably 130° C. to 300° C., and particularly preferably 200° C. to 300° C.

The heating time is preferably 10 seconds to 60 minutes, more preferably 1 minute to 30 minutes, and still more preferably 3 minutes to 10 minutes.

After the substrate and the present composition are brought into contact with each other, it is also preferable to perform a rinsing treatment. By the rinsing treatment, it is possible to remove the present composition and/or impurities, adhering to a region other than a desired region (for example, a region interacting with the specific functional group in the specific compound) on the substrate, from the substrate.

A rinsing method is not particularly limited and examples thereof include a method of bringing a rinsing liquid into contact with the substrate. The same method as the method of bringing the substrate into contact with the present composition can be used as the above-described contact method.

The temperature of the rinsing liquid in the contact is not particularly limited, and is preferably 0° C. to 50° C. and more preferably 10° C. to 30° C.

A known organic solvent can be used as the rinsing liquid, and for example, the alcohol-based solvent, the ether-based solvent, the ester-based solvent, and the like described above can be used. In addition, it is also preferable that the solvent contained in the present composition is used as the rinsing liquid.

### [Manufacturing Method of Laminate]

The manufacturing method of a laminate according to the embodiment of the present invention includes a step 1 of bringing a substrate having at least two types of surfaces of a first surface and a second surface, each surface being composed of a different material, (hereinafter, also referred to as “specific substrate”) into contact with the present composition to form a first coating film on the first surface, and a step 2 of performing the ALD treatment on the substrate obtained in the step 1 to form a second coating film on the second surface.

As a result, a laminate having the second coating film (ALD film) on the second surface is obtained.

### [Step 1: Manufacturing Method of Modified Substrate]

The step 1 is a step of bringing the specific substrate into contact with the present composition to form a first coating film on the first surface. A modified substrate 1 having the first coating film formed on the first surface of the specific substrate is obtained by the step 1. The first coating film is a coating film containing components (for example, the specific compound) contained in the present composition, other than the solvent.

A method of bringing the specific substrate into contact with the present composition is not particularly limited, and the method of bringing the substrate into contact with the present composition in the manufacturing method of a modified substrate described above can be used.

It is also preferable that the coating film is subjected to a heating treatment after the specific substrate and the present composition are brought into contact with each other.

The heating method is not particularly limited, and the heating method in the manufacturing method of a modified substrate described above can be used.

It is also preferable to perform a rinsing treatment on the modified substrate 1 in which the first coating film is formed on the first surface. By the rinsing treatment, it is possible to remove the present composition and/or impurities, adhering to a region (for example, the second surface) other than the first surface on the specific substrate, from the specific substrate.

As the rinsing method, the rinsing method in the manufacturing method of a modified substrate described above can be used.

### [Step 2: ALD Treatment]

The step 2 is a step of performing the ALD treatment on the modified substrate 1 obtained in the above-described step 1 to form a second coating film on the second surface.

A laminate 1 in which the first coating film is formed on the first surface and the second coating film is formed on the second surface is obtained by the step 2. The second coating film is a film formed by the ALD treatment (ALD film).

The above-described modified substrate 1 may be any substrate in which the first coating film is formed on the first surface of the specific substrate by the above-described step 1, and the heating treatment, the rinsing treatment, and the like described above may be performed after the step 1.

A method of the ALD treatment is not particularly limited, and a known method can be used, but a thermal ALD method is preferable. In a case of using the thermal ALD method, the reaction between the carbon-carbon triple bonds in the specific compounds in the first coating film may proceed in the thermal ALD method.

From the viewpoint that the effect of the present invention is more excellent, a substrate heating temperature in the ALD treatment is preferably 100° C. to 400° C., more preferably 150° C. to 400° C., and still more preferably 250° C. to 350° C.

Examples thereof include a method in which a gas of a precursor which is a raw material for the ALD film is supplied to the surface of the modified substrate 1, and then the raw material is decomposed and/or chemically reacted with an oxidant or the like to deposit the material, thereby forming the ALD film.

The above-described precursor is not particularly limited, and a known precursor can be used depending on the type of the ALD film to be formed; and examples thereof include an organic metal compound. Compounds described in paragraphs to of JP2022-080800A, and the like can be used as the precursor.

The above-described oxidant is not particularly limited, and any known oxidant used for the ALD treatment can be used; and examples thereof include water, oxygen, and ozone.

The material constituting the above-described ALD film can be adjusted by the type of the precursor to be supplied, the supply atmosphere, the oxidant, and the like.

The material for the ALD film to be formed is not particularly limited, and examples thereof include a metal, a metal oxide, and a metal nitride. Examples of the metal include aluminum, titanium, chromium, iron, cobalt, nickel, copper, zinc, yttrium, zirconium, niobium, molybdenum, ruthenium, palladium, lanthanum, cerium, hafnium, tantalum, tungsten, platinum, and bismuth. Examples of the metal oxide include aluminum oxide, titanium oxide, zinc oxide, zirconium oxide, hafnium oxide, and tantalum oxide. Examples of the metal nitride include titanium nitride and tantalum nitride.

In the ALD treatment, a treatment for modifying a surface of a region where the first coating film is not formed may be performed.

A thickness of the material deposited on the first coating film after the ALD treatment is preferably as thin as possible, and is preferably 4.0 nm or less, more preferably 2.0 nm or less, and still more preferably 1.0 nm or less. The lower limit thereof is 0 nm or more, and may be 0 nm.

A ratio of the thickness of the material deposited on the region where the first coating film is formed to a thickness of the second coating film is preferably 0.75 or less, more preferably 0.5 or less, and still more preferably 0.25 or less. The lower limit of the above-described ratio is 0 or more, and may be 0.

### [Step 3: Removal of Coating Film]

The manufacturing method of a laminate according to the embodiment of the present invention may include, after the step 2, a step 3 of removing the first coating film formed on the first surface in the step 1. A laminate 2 having no coating film on the first surface and having the second coating film on the second surface is obtained by the step 3.

A method of removing the first coating film is not particularly limited, and examples thereof include dry etching, wet etching, and a combination thereof.

A known method can be used as the dry etching, and for example, chemical dry etching in which reactive ions or reactive radicals are supplied to the surface of the laminate 1, physical dry etching such as sputter etching and ion beam etching, and the like can be used.

For the wet etching, a method in which an etchant is supplied to the laminate 1 can be used. Examples of the etchant include an etchant containing an oxidant such as ozone and hydrofluoric acid, and an etchant containing an organic solvent. Examples of the organic solvent include the organic solvent contained in the above-described composition, and an alcohol-based solvent, an ester-based solvent, a ketone-based solvent, or a hydrocarbon-based solvent is preferable.

Among these, chemical dry etching or wet etching is preferable.

### [Manufacturing Method of Electronic Device]

The manufacturing method of a modified substrate and the manufacturing method of a laminate described above can be suitably applied to a manufacturing method of an electronic device. The manufacturing method of an electronic device according to the embodiment of the present invention preferably includes the manufacturing method of a modified substrate, and more preferably includes the manufacturing method of a laminate.

The above-described manufacturing method of a modified substrate may be performed in combination before or after other steps performed on the substrate. Other steps may be incorporated into the above-described manufacturing method of a modified substrate, or the above-described manufacturing method of a modified substrate may be incorporated into other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described treatment method may be performed at any stage of a back-end process (back end of the line; BEOL), a middle process (middle of the line; MOL), and a front-end process (front end of the line; FEOL).

### [Compound]

The present invention also includes a compound. The compound in the present invention is the above-described specific compound.

From the viewpoint that the effect of the present invention is more excellent, the specific compound is preferably a compound represented by General Formula (2) or a compound represented by General Formula (3).

Hereinafter, the compound represented by General Formula (2) will be described in detail.

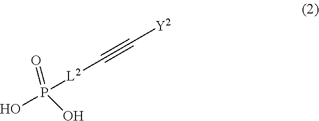

In General Formula (2),
L² represents a divalent linking group including a divalent aromatic group, and
Y² represents an aliphatic hydrocarbon group having 8 or more carbon atoms, which may have a substituent, or an aromatic group which may have a substituent.

The definition and suitable aspect of the divalent linking group including a divalent aromatic group, represented by L², are as described in the requirement Y¹.

The divalent linking group including a divalent aromatic group is preferably an arylene group having 6 to 20 carbon atoms or -alkylene group-O-arylene group having 6 to 20 carbon atoms, and more preferably a phenylene group or -alkylene group-O-phenylene group-.

The number of carbon atoms in the above-described alkylene group is preferably 6 to 30.

Examples of the aliphatic hydrocarbon group having 8 or more carbon atoms, which may have a substituent and is represented by Y², include groups having 8 or more carbon atoms among the aliphatic hydrocarbon groups having 6 or more carbon atoms, described in the requirement X2.

The aliphatic hydrocarbon group having 8 or more carbon atoms, which may have a substituent, is preferably an alkyl group having 8 to 28 carbon atoms, and more preferably an alkyl group having 10 to 24 carbon atoms.

The definition and suitable aspect of the aromatic group which may have a substituent and is represented by Y² are as described in the requirement Y².

Subsequently, the compound represented by General Formula (3) will be described in detail.

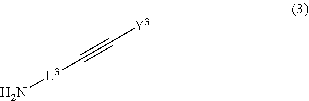

In General Formula (3),
L³ represents a divalent linking group including a divalent aromatic group, and
Y³ represents an aliphatic hydrocarbon group having 8 or more carbon atoms, which may have a substituent, or an aromatic group which may have a substituent.

The definition and suitable aspect of the divalent linking group including a divalent aromatic group, represented by L³, are the same as the definition and suitable aspect of the divalent linking group including a divalent aromatic group, represented by L², in General Formula (2).

The definition and suitable aspect of the aliphatic hydrocarbon group having 8 or more carbon atoms, which may have a substituent and is represented by Y³, and the definition and suitable aspect of the aromatic group which may have a substituent are the same as the definition and suitable aspect of the aliphatic hydrocarbon group having 8 or more carbon atoms, which may have a substituent and is represented by Y², and the definition and suitable aspect of the aromatic group which may have a substituent in General Formula (2).

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

The preparation, filling, storage, and the like of the composition were all carried out in a clean room satisfying a level equal to or lower than ISO Class 2. In addition, the container used for the preparation, filling, storage, and the like of the composition was used after being washed with the solvent used for the preparation or the prepared composition.

### [Preparation of Present Composition]

Each component used for preparation of the composition according to the embodiment of the present invention is shown below.

### [Specific Compound E-1]

A specific compound E-1 was synthesized as follows.

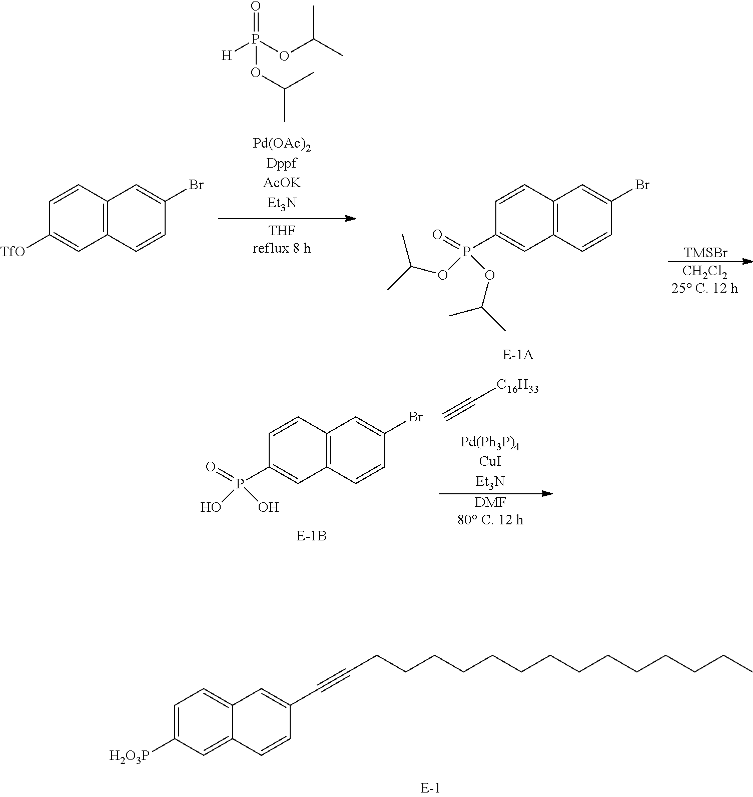

### <Synthesis of Intermediate E-1A>

Under a nitrogen flow (30 mL/min), palladium acetate (0.32 g, 1.4 mol, manufactured by Tokyo Chemical Industry Co., Ltd.) and tetrahydrofuran (THF, 200 mL, manufactured by FUJIFILM Wako Pure Chemical Corporation) were charged into a three-neck flask, and the mixture was stirred. 1,1′-Bis(diphenylphosphino)ferrocene (Dppf, 1.56 g, 2.8 mol, manufactured by Tokyo Chemical Industry Co., Ltd.), triethylamine (6.84 g, 67.6 mmol, manufactured by Kanto Chemical Co., Inc.), and potassium acetate (0.55 g, 5.6 mmol, manufactured by FUJIFILM Wako Pure Chemical Corporation) were further added thereto, and the mixture was stirred at 25° C. for 0.5 hours. Thereafter, diisopropyl phosphite (5.15 g, 31.0 mmol, manufactured by Tokyo Chemical Industry Co., Ltd.) and 6-Bromo-2-naphthyl triflate (10.0 g, 28.2 mol, manufactured by Kanto Chemical Co., Inc.) were added thereto, and the obtained reaction solution was stirred under reflux for 8 hours.

After cooling the reaction solution to 25° C., insoluble matter was filtered and removed using a Nutsche filled with Celite. The solvent was distilled off from the filtrate under a reduced pressure of 40° C./10 hPa, ethyl acetate (300 mL, manufactured by FUJIFILM Wako Pure Chemical Corporation) and 1 M hydrochloric acid (150 mL) were added thereto, and the obtained solution was transferred to a separating funnel and stirred. After allowing the solution to stand, the lower phase (water phase) was removed and the upper phase (organic phase) was recovered. The solvent was distilled off from the obtained organic phase under reduced pressure of 40° C./10 hPa.

The obtained crude product was purified by silica gel column chromatography to obtain an intermediate E-1A.

### <Synthesis of Intermediate E-1B>

The intermediate E-1A (6.50 g, 17.5 mol) and dichloromethane (130 mL, manufactured by FUJIFILM Wako Pure Chemical Corporation) were charged into a three-neck flask, and the mixed solution was cooled to 0° C. Bromotrimethylsilane (TMSBr, 26.8 g, 175.1 mmol, manufactured by FUJIFILM Wako Pure Chemical Corporation) was added to the obtained mixed solution, the mixture was stirred at 0° C. for 24 hours, MeOH (150 mL, manufactured by Mitsubishi Gas Chemical Company, Inc.) was added to the reaction solution, and the mixture was stirred at 25° C. for 12 hours.

The obtained solution was concentrated, diisopropyl ether (50 mL, manufactured by FUJIFILM Wako Pure Chemical Corporation) was added thereto, and the mixture was stirred. After allowing the solution to stand, the supernatant solution was removed, and dichloromethane (130 mL) was added thereto, and the mixture was cooled to 0° C. The precipitated crystals were collected by filtration to obtain an intermediate E-1B.

### <Synthesis of Specific Compound E-1>

Under a nitrogen flow (10 mL/min), the intermediate E-1B (1.90 g, 6.6 mmol) and dimethylformamide (DMF, 25 mL, manufactured by FUJIFILM Wako Pure Chemical Corporation) were charged into a three-neck flask, and the mixture was stirred. Triethylamine (13.40 g, 132.4 mmol), 1-octadecyne (2.49 g, 9.9 mmol, manufactured by Tokyo Chemical Industry Co., Ltd.), copper iodide (0.13 g, 0.7 mmol, manufactured by FUJIFILM Wako Pure Chemical Corporation), and tetrakis(triphenylphosphine)palladium(0) (Pd(Ph₃P)₄, 0.38 g, 0.3 mmol, manufactured by Tokyo Chemical Industry Co., Ltd.) were added thereto, and the reaction solution was stirred at 80° C. for 12 hours.

While maintaining the temperature of the reaction solution at 80° C., insoluble matter was filtered and removed using a Nutsche filled with Celite. The filtrate was cooled to 0° C., MeOH (30 mL) and 1 M hydrochloric acid (30 mL) were added thereto, and the mixture was stirred at 0° C. for 0.5 hours.

The obtained crystals were collected by filtration, and washed again with MeOH (30 mL) to obtain a specific compound E-1.

¹H-NMR (nuclear magnetic resonance) data of the obtained specific compound E-1 is shown below.

¹H-NMR (400 MHz, THF-d8): δ (ppm)=8.31 (d, J=15.0 Hz, 1H), 7.90 (s, 1H), 7.74 to 7.85 (m, 3H), 7.44 (dd, J=1.1 Hz, 8.5 Hz, 1H), 3.40 to 4.10 (br, 2H), 2.46 (t, J=7.0 Hz, 2H), 1.64 (m, 2H), 1.51 (m, 2H), 1.20 to 1.43 (m, 26H), 0.89 (t, J=7.0 Hz, 3H)

### [Specific Compound E-7]

A compound E-7 was synthesized as follows.

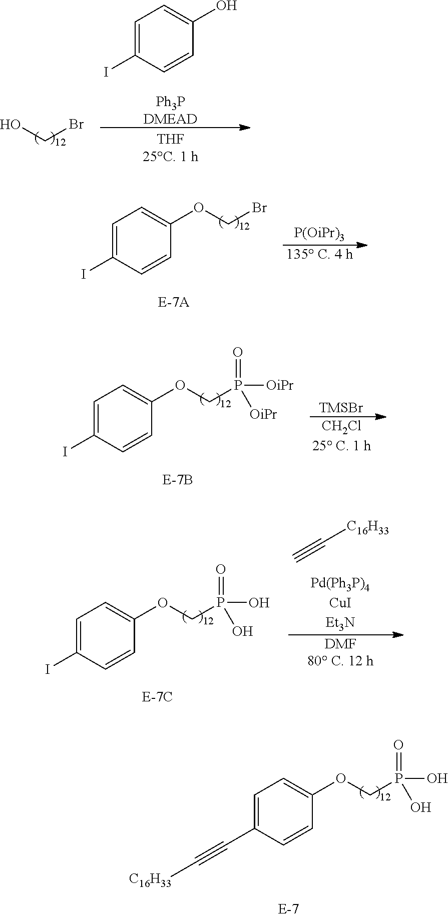

### <Synthesis of Intermediate E-7A>

Under a nitrogen flow (50 mL/min), 12-bromo-1-dodecanol (15.0 g, 56.6 mmol, manufactured by Tokyo Chemical Industry Co., Ltd.), triphenylphosphine (22.3 g, 84.8 mmol, manufactured by FUJIFILM Wako Pure Chemical Corporation), 4-iodophenol (16.2 g, 73.5 mmol, manufactured by Tokyo Chemical Industry Co., Ltd.), and THF (188 mL) were charged into a three-neck flask, and the reaction solution was cooled to 0° C. Next, a dissolving solution obtained by dissolving bis(2-methoxyethyl) azodicarboxylate (DMEAD (registered trademark), 19.9 g, 84.8 mmol, manufactured by FUJIFILM Wako Pure Chemical Corporation) in THF (94 mL) was separately prepared.

While maintaining the internal temperature of the reaction solution obtained above at 5° C. or lower, the above-described dissolving solution was added dropwise to the reaction solution over 4 hours. After completion of the dropwise addition, the reaction solution was stirred at 25° C. for 1 hour.

Next, the solvent was distilled off from the reaction solution under a reduced pressure of 40° C./10 hPa. After the distillation, ethyl acetate (500 mL, manufactured by FUJIFILM Wako Pure Chemical Corporation) and a 1 M sodium hydroxide aqueous solution (250 mL) were added thereto, and the obtained solution was transferred to a separating funnel and stirred. After allowing the solution to stand, the lower phase (water phase) was removed, and distilled water (400 mL) was added to the upper phase (organic phase) and stirred. After allowing the solution to stand, the lower phase (water phase) was removed and the upper phase (organic phase) was recovered. The solvent was distilled off from the obtained organic phase under a reduced pressure of 40° C./10 hPa to obtain a 40% by mass ethyl acetate solution.

Methanol (260 mL, manufactured by FUJIFILM Wako Pure Chemical Corporation) was added to the obtained 40% by mass ethyl acetate solution, and the mixed solution was cooled to 0° C. The mixed solution was stirred at 0° C. for 30 minutes, the precipitated crystals were washed with methanol, and then dried by blast drying at 40° C. for 12 hours to obtain an intermediate E-7A.

### <Synthesis of Intermediate E-7B>

The intermediate E-7A (12.7 g, 27.2 mmol) and triisopropyl phosphite (14.2 g, 68.2 mol, manufactured by Tokyo Chemical Industry Co., Ltd.) were charged into a three-neck flask, and the obtained mixed solution was stirred at 135° C. for 4 hours.

Next, the excess triisopropyl phosphite used was distilled off from the reaction solution under a reduced pressure of 70° C./5 hPa, and the obtained crude product was purified by silica gel column chromatography to obtain an intermediate E-7B.

### <Synthesis of Intermediate E-7C>

The intermediate E-7B (18.3 g, 33.1 mol) and dichloromethane (150 mL, manufactured by FUJIFILM Wako Pure Chemical Corporation) were charged into a three-neck flask, and the mixed solution was cooled to 0° C. Bromotrimethylsilane (TMSBr, 15.2 g, 99.3 mmol, manufactured by FUJIFILM Wako Pure Chemical Corporation) was added to the obtained mixed solution, the mixture was stirred at 0° C. for 4 hours, methanol (150 mL) was added to the reaction solution, and the mixture was stirred at 25° C. for 1 hour.

The obtained solution was concentrated, diisopropyl ether was added thereto, and the mixture was stirred at 25° C. for 1 hour. The precipitated crystals were collected by filtration, washed with diisopropyl ether, and then dried by blast drying at 40° C. for 12 hours to obtain an intermediate E-7C.

### <Synthesis of Specific Compound E-7>

Under a nitrogen flow (10 mL/min), the intermediate E-7C (3.0 g, 5.4 mmol) and DMF (40 mL, manufactured by FUJIFILM Wako Pure Chemical Corporation) were charged into a three-neck flask, and the mixture was stirred. Triethylamine (11.0 g, 108.6 mmol), 1-octadecyne (2.0 g, 8.1 mmol, manufactured by Tokyo Chemical Industry Co., Ltd.), copper iodide (0.1 g, 0.5 mmol, manufactured by FUJIFILM Wako Pure Chemical Corporation), and tetrakis(triphenylphosphine)palladium(0) 0.31 g, 0.3 mmol, manufactured by Tokyo Chemical Industry Co., Ltd.) were added thereto, and the reaction solution was stirred at 80° C. for 12 hours.

While maintaining the temperature of the reaction solution at 40° C., insoluble matter was filtered and removed using a Nutsche filled with Celite. The filtrate was cooled to 0° C. and stirred for 0.5 hours. After the crystals were precipitated, the obtained crystals and 1 M hydrochloric acid (40 mL) were added to a eggplant flask, and the mixture was stirred at 25° C. for 1 hour. The crystals were collected by filtration and recrystallized with THF (30 mL) to obtain a specific compound E-7.

¹H-NMR data of the obtained specific compound E-7 is shown below.

¹H-NMR (400 MHz, THF-d8): δ (ppm)=7.23 (d, J=8.7 Hz, 2H), 6.79 (d, J=8.7 Hz, 2H), 3.93 (t, J=6.4 Hz, 2H), 2.35 (t, J=6.9 Hz, 2H), 1.66 to 1.84 (m, 2H), 1.51 to 1.65 (m, 6H), 1.40 to 1.50 (m, 4H), 1.20 to 1.40 (m, 38H), 0.89 (t, J=6.5 Hz, 2H)

### [Specific Compound E-18]

A specific compound E-18 was synthesized as follows.

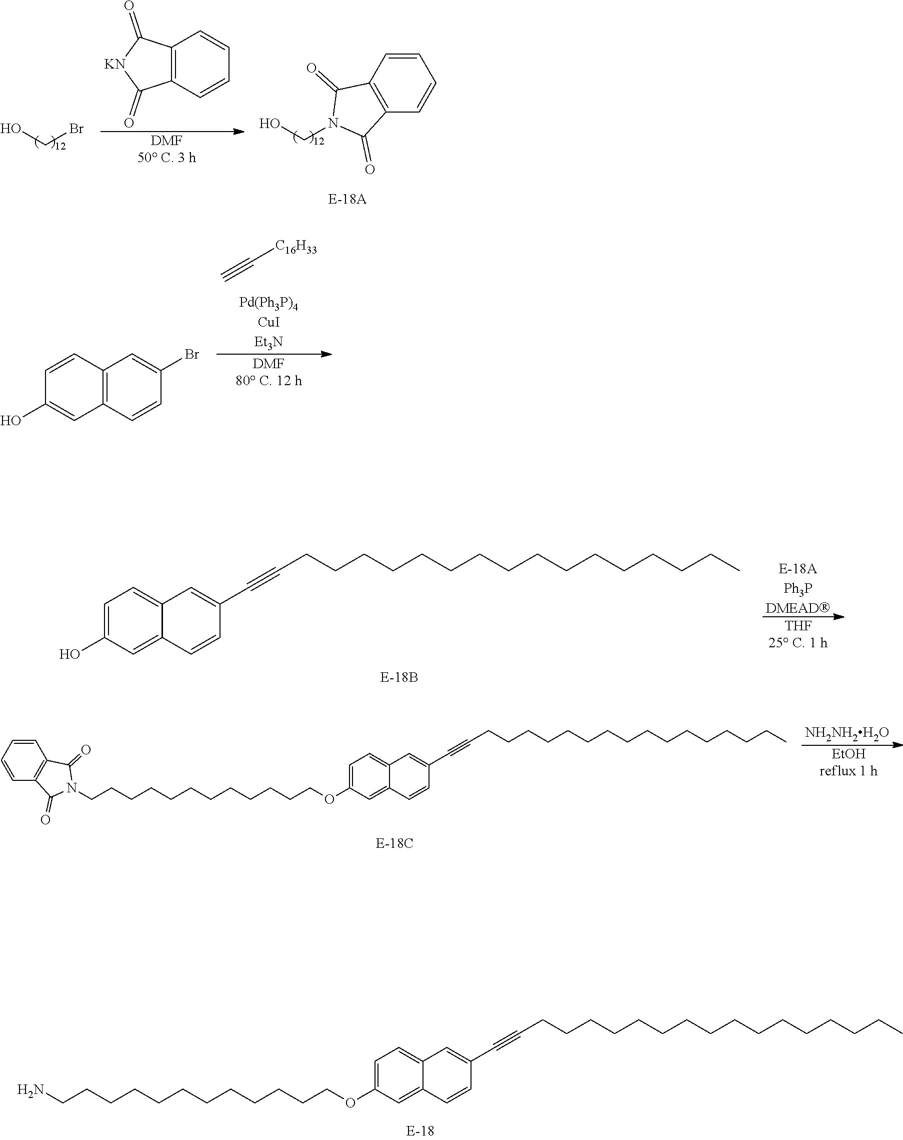

### <Synthesis of Intermediate E-18A>

Under a nitrogen flow (0.1 L/min), 12-bromo-1-dodecanol (50.0 g, 0.19 mol, manufactured by Tokyo Chemical Industry Co., Ltd.), DMF (250 mL, manufactured by FUJIFILM Wako Pure Chemical Corporation), and phthalimide potassium (38.4 g, 0.21 mol, manufactured by Tokyo Chemical Industry Co., Ltd.) were charged into a three-neck flask, and the obtained mixed solution was stirred at 50° C. for 3 hours.

After the obtained reaction solution was cooled to 25° C., insoluble matter was removed by filtration, and the filtrate was washed with DMF (50 mL) to obtain a filtrate A.

Distilled water (900 mL) was charged into a beaker, and stirred at 25° C., and the above-described filtrate A was added dropwise thereto. The obtained crystals were collected by filtration, washed twice with distilled water (200 mL), and then dried by blast drying at 40° C. for 24 hours to obtain an intermediate E-18A.

### <Synthesis of Intermediate E-18B>

Under a nitrogen flow (10 mL/min), 6-bromo-2-naphthol (50.0 g, 0.22 mol, manufactured by FUJIFILM Wako Pure Chemical Corporation) and DMF (670 mL, manufactured by FUJIFILM Wako Pure Chemical Corporation) were charged into a three-neck flask, and the mixture was stirred. Triethylamine (453.6 g, 4.48 mol), 1-octadecyne (84.2 g, 0.34 mmol, manufactured by Tokyo Chemical Industry Co., Ltd.), copper iodide (4.3 g, 0.02 mmol, manufactured by FUJIFILM Wako Pure Chemical Corporation), and tetrakis(triphenylphosphine)palladium(0) 13.0 g, 0.01 mmol, manufactured by Tokyo Chemical Industry Co., Ltd.) were added thereto, and the reaction solution was stirred at 80° C. for 12 hours.

After the reaction was completed, the reaction solution was cooled to 25° C., and insoluble matter was filtered and removed using a Nutsche filled with Celite. The crude product obtained by concentrating the obtained filtrate was purified by silica gel chromatography to obtain an intermediate E-18B.

### <Synthesis of Intermediate E-18C>

Under a nitrogen flow (50 mL/min), E-18A (5.8 g, 17.5 mmol), triphenylphosphine (6.88 g, 26.2 mol, manufactured by FUJIFILM Wako Pure Chemical Corporation), E-18B (7.56 g, 19.2 mmol), and THF (87 mL) were charged into a three-neck flask, and the mixture was cooled to 0° C. Next, a dissolving solution obtained by dissolving bis(2-methoxyethyl) azodicarboxylate (DMEAD (registered trademark), 6.15 g, 26.2 mmol, manufactured by FUJIFILM Wako Pure Chemical Corporation) in THF (29 mL) was separately prepared.

While maintaining the internal temperature of the reaction solution obtained above at 5° C. or lower, the above-described dissolving solution was added dropwise to the reaction solution over 4 hours. After completion of the dropwise addition, the reaction solution was stirred at 25° C. for 1 hour.

The obtained crystals were collected by filtration, washed with methanol, and then dried by blast drying at 40° C. for 12 hours to obtain an intermediate E-18C.

### <Synthesis of Specific Compound E-18>

Under a nitrogen flow (0.1 L/min), the intermediate E-18C (4.72 g, 6.6 mmol) and ethanol (63 mL, manufactured by FUJIFILM Wako Pure Chemical Corporation) were charged into a three-neck flask, and the mixed solution was stirred. Hydrazine monohydrate (1.34 g, 26.7 mmol, manufactured by FUJIFILM Wako Pure Chemical Corporation) was added to the obtained mixed solution, and the reaction solution was heated under reflux for 1 hour.

Thereafter, the obtained reaction solution was cooled to 20° C., and the crystals obtained were collected by filtration, slurry-washed with a 1 M sodium hydroxide aqueous solution, and then washed with water. Thereafter, the obtained crystals were dried by blast drying at 40° C. for 12 hours to obtain a specific compound E-18.

¹H-NMR data of the obtained specific compound E-18 is shown below.

¹H-NMR (400 MHz, THF-d8): δ (ppm)=7.77 (s, 1H), 7.66 (d, J=9.0 Hz, 1H), 7.62 (d, J=8.6 Hz, 1H), 7.33 (dd, J=1.6, 8.4 Hz, 1H), 7.16 (d, J=2.4 Hz, 1H), 7.10 (dd, J=2.5, 8.9 Hz, 1H), 4.07 (t, J=6.5 Hz, 2H), 2.59 (t, J=6.6 Hz, 2H), 2.42 (t, J=6.9 Hz, 2H), 1.78 to 1.87 (m, 2H), 1.57 to 1.66 (m, 2H), 1.45 to 1.56 (m, 4H), 1.20 to 1.45 (m, 40H), 0.88 (t, J=6.7 Hz, 3H)

[Specific Compound and comparative compound]

Structures of each specific compound and comparative compound used for the preparation of the compositions of Examples and Comparative Examples are shown below. The specific compounds other than E-1, E-7, and E-18 were synthesized in the same manner according to the synthesis procedure of E-1, E-7, or E-18 described above. A numerical value shown below the structural formula of each specific compound indicates the molecular weight of each specific compound.

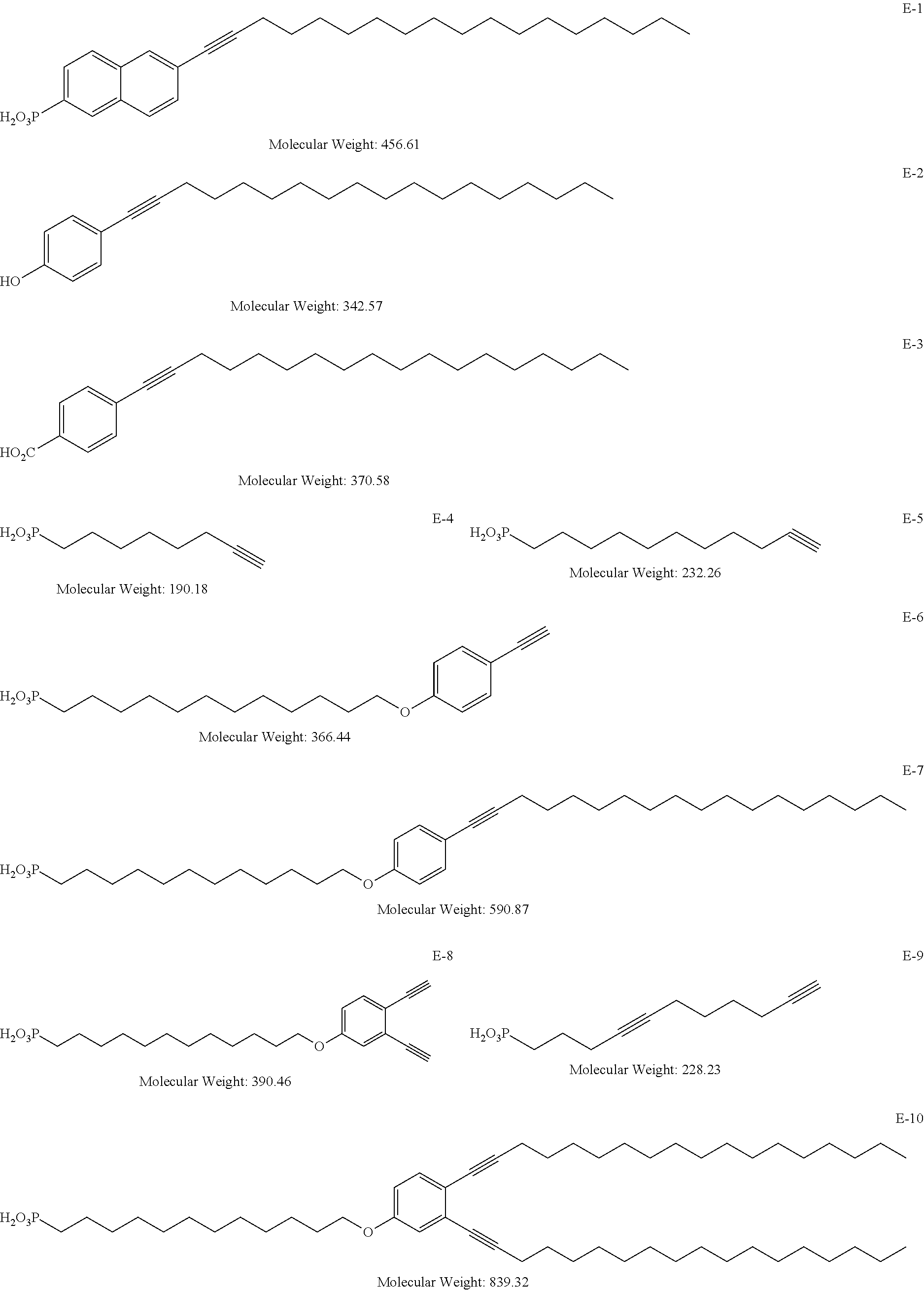

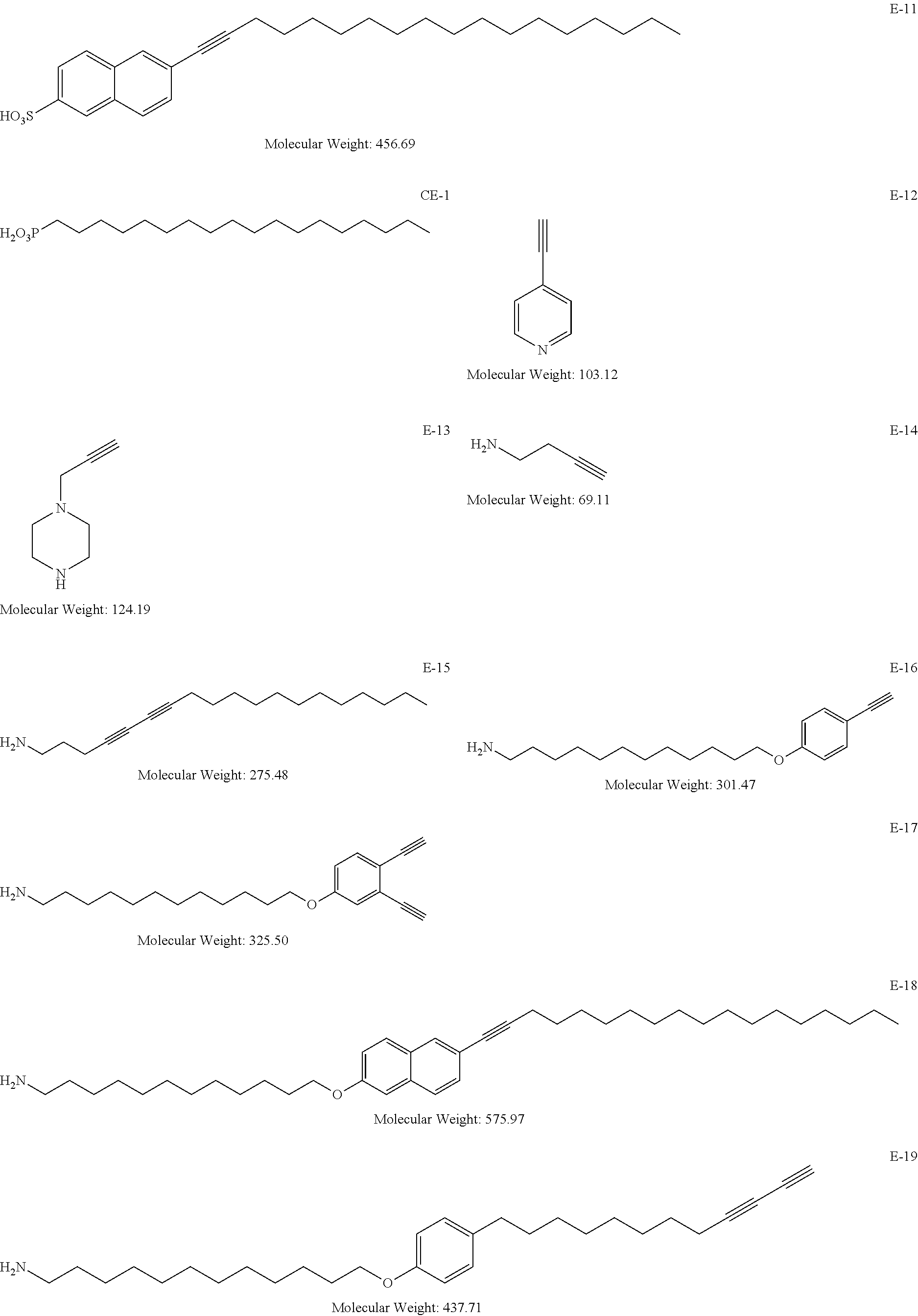

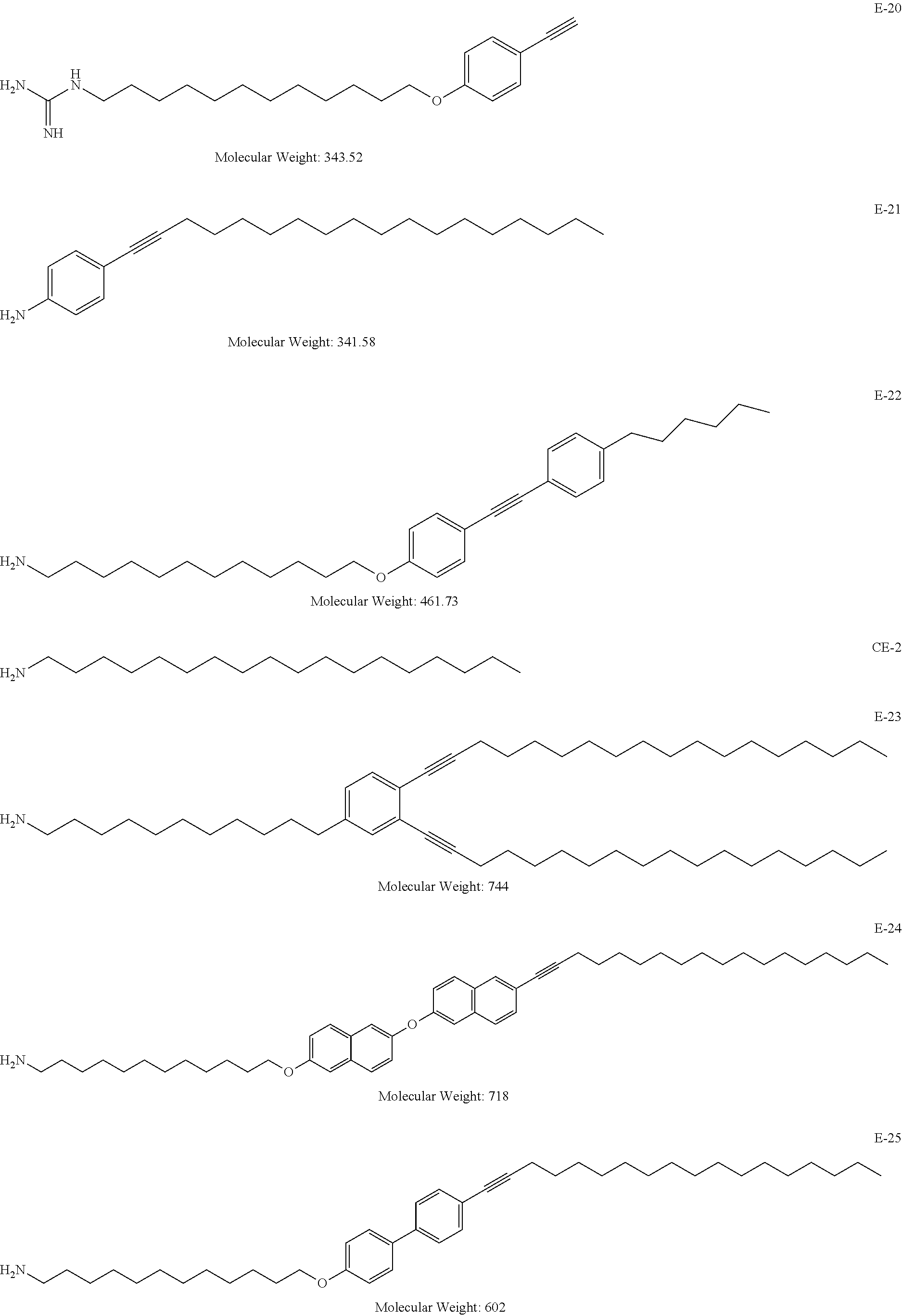

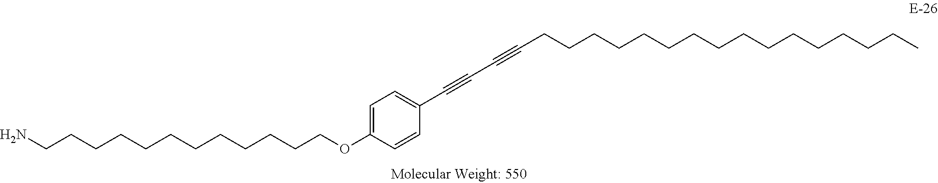 [SMILES: CCCCCCCCCCCCCCCCC#CC#Cc1ccc(OCCCCCCCCCCCCN)cc1]

### [Polymerization Inhibitor]

TEMPO: 2,2,6,6-tetramethylpiperidine 1-oxyl
BHT: 2,6-di-tert-butyl-p-cresol

### [Solvent]

PGMEA: propylene glycol monomethyl ether acetate
PGME: propylene glycol monomethyl ether
MIBC: methyl isobutyl carbinol
IPA: Isopropyl alcohol
H₂O: pure water

### [Preparation of Liquid]

The composition of each of Examples and Comparative Examples was prepared by mixing the specific compound or the comparative compound, the solvent, and, as necessary, the polymerization inhibitor with the formulation shown in Tables 1 to 3.

### [Production of Modified Substrate]

As a substrate, a W layer-wafer in which a W (tungsten) layer was formed on one surface of a commercially available silicon wafer (diameter: 12 inches) by a CVD method, a Co layer-wafer in which a Co (cobalt) layer was formed on one surface of the commercially available silicon wafer by a sputtering method, and a Mo layer-wafer in which a Mo (molybdenum) layer was formed on one surface of the commercially available silicon wafer by a CVD method were prepared. Film formation conditions were adjusted such that the thicknesses of the W layer, the Co layer, and the Mo layer were 20 nm.

The above-described silicon wafer, W layer-wafer, Co layer-wafer, and Mo layer-wafer were cut into 2 cm square pieces and washed by being immersed in isopropyl alcohol (IPA). The washing was carried out while stirring IPA at a stirring speed of 250 rpm, setting the temperature of IPA to 25° C., and setting the washing time to 30 seconds. The wafer after the washing was dried by blowing nitrogen gas onto the wafer.

Next, each wafer after the washing was immersed in each composition to carry out a modification treatment on the wafer. The above-described immersion was carried out while stirring the composition at a stirring speed of 250 rpm, setting the temperature of the composition to 25° C., and setting the immersion time to 10 minutes.

Each wafer after the immersion was subjected to a rinsing treatment by immersing the wafer in IPA. The rinsing treatment was carried out while stirring IPA at a stirring speed of 250 rpm, setting the temperature of IPA to 25° C., and setting the rinsing time to 30 seconds. The wafer after the rinsing was dried by blowing nitrogen gas onto the wafer.

A modified substrate was obtained by the above procedure.

### [Evaluation]

[Evaluation of Pure Water Contact Angle after Substrate Modification]

For each modified substrate obtained in [Production of modified substrate] and a substrate (unmodified substrate) before being immersed in each composition, using a contact angle meter (DMs-501, manufactured by Kyowa Interface Science Co., Ltd.), values of contact angles 500 milliseconds after a liquid droplet of water was in contact with the surface of a measurement object were measured three times at 23° C., and an average value of the measured values was defined as a contact angle (deg. (degree)). The analysis was carried out with a surface tension of pure water set to 72.9 mN/m.

### [Evaluation of ALD Inhibition Properties]

For the W layer-wafer, the Co layer-wafer, or the Mo layer-wafer after the modification treatment, which was obtained by [Production of modified substrate], and the W layer-wafer, the Co layer-wafer, or the Mo layer-wafer (unmodified substrate) before being immersed in each composition, using an atomic layer deposition device (AD-230LP, manufactured by SAMCO INC.), an aluminum oxide (Al₂O₃) layer (ALD film) was formed by the ALD method. Trimethylaluminum was used as an organic metal raw material, water was used as an oxidant, and the ALD treatment temperature was set to 200° C. Other conditions were adjusted such that a film thickness of the ALD film formed on the unmodified substrate was 5 nm.

The film thickness of the ALD film of each sample after the ALD treatment was measured using an X-ray fluorescence (XRF) analyzer (AZX400, manufactured by Rigaku Corporation). The measurement was carried out at five points on the substrate, and an average value of the measured values was defined as the film thickness.

The ALD inhibition properties were evaluated according to the following evaluation standard from the obtained film thickness. As the above-described film thickness was smaller, the film was less likely to be deposited by the ALD treatment, that is, the ALD inhibition properties were excellent. The ALD inhibition properties are preferably D or higher.

S: film thickness of the ALD film was less than 0.5 nm.

A: film thickness of the ALD film was 0.5 nm or more and less than 1.0 nm.

B: film thickness of the ALD film was 1.0 nm or more and less than 1.5 nm.

C: film thickness of the ALD film was 1.5 nm or more and less than 2.0 nm.

D: film thickness of the ALD film was 2.0 nm or more and less than 2.5 nm.

E: film thickness of the ALD film was 2.5 nm or more.

Tables 1 to 3 show the formulations and evaluation results of each composition. Table 1 shows the result of evaluating the selectivity of the Co layer-wafer with respect to the silicon wafer; Table 2 shows the result of evaluating the selectivity of the W layer-wafer with respect to the silicon wafer; and Table 3 shows the result of evaluating the selectivity of the Mo layer-wafer with respect to the silicon wafer.

In Table 1, the numerical value in the column of “pKa” indicates the acid dissociation constant of the specific functional group in the specific compound.

In Tables 2 and 3, the numerical value in the column of “pKa” indicates the acid dissociation constant of the conjugate acid of the compound, which is obtained by adding a proton to the specific functional group in the specific compound. However, in Example C1, the acid dissociation constant of the specific functional group in the specific compound is indicated.

In the tables, the content of the solvent is a remainder obtained by subtracting the total mass of components (the specific compound or the comparative compound, the solvent, and the polymerization inhibitor) other than the solvent from the total mass of all components of the composition, in a case where the total mass of all components of the composition is set to 100 parts by mass.

TABLE 1

| | | | Example | Example | Example | Example | Example |
|---|---|---|---|---|---|---|---|
| Table 1 | | | A1 | A2 | A3 | A4 | A5 |
| Composition | Specific | Type | E-1 | E-2 | E-3 | E-4 | E-5 |
| | compound or | Amount | 0.05 | 0.05 | 0.05 | 0.05 | 0.05 |
| | comparative | (part by | | | | | |
| | compound | mass) | | | | | |
| | | Type | — | — | — | — | — |
| | | Amount | — | — | — | — | — |
| | | (part by | | | | | |
| | | mass) | | | | | |
| | | pKa | 1.8 | 9.8 | 4.2 | 2.4 | 2.4 |
| | Polymerization | Type | — | — | — | — | — |
| | inhibitor | Amount | — | — | — | — | — |
| | | (part by | | | | | |
| | | mass) | | | | | |
| | Solvent | Type | PGME | PGME | PGME | PGME | PGME |
| | | Amount | Remainder | Remainder | Remainder | Remainder | Remainder |
| | | (part by | | | | | |
| | | mass) | | | | | |
| | Total (part by mass) | | 100 | 100 | 100 | 100 | 100 |
| Evaluation | Pure water | Co | 97 | 90 | 92 | 87 | 87 |
| | contact angle | Si | 21 | 20 | 19 | 22 | 20 |
| | after substrate | | | | | | |
| | modification | | | | | | |
| | (deg.) | | | | | | |
| | Al₂O₃ vapor | Co | S | D | C | C | B |
| | deposition | | | | | | |
| | inhibition | | | | | | |
| | properties | | | | | | |
| | | | Example | Example | Example | Example | Example |
| Table 1 | | | A6 | A7 | A8 | A9 | A10 |
| Composition | Specific | Type | E-6 | E-7 | E-8 | E-9 | E-10 |
| | compound or | Amount | 0.05 | 0.05 | 0.05 | 0.05 | 0.05 |
| | comparative | (part by | | | | | |
| | compound | mass) | | | | | |
| | | Type | — | — | — | — | — |
| | | Amount | — | — | — | — | — |
| | | (part by | | | | | |
| | | mass) | | | | | |
| | | pKa | 2.4 | 2.4 | 2.4 | 2.2 | 1.9 |
| | Polymerization | Type | — | — | — | — | — |
| | inhibitor | Amount | — | — | — | — | — |
| | | (part by | | | | | |
| | | mass) | | | | | |
| | Solvent | Type | PGME | PGME | PGME | PGME | PGMEA |
| | | Amount | Remainder | Remainder | Remainder | Remainder | Remainder |
| | | (part by | | | | | |
| | | mass) | | | | | |
| | Total (part by mass) | | 100 | 100 | 100 | 100 | 100 |
| Evaluation | Pure water | Co | 72 | 102 | 75 | 90 | 100 |
| | contact angle | Si | 22 | 21 | 20 | 20 | 21 |
| | after substrate | | | | | | |
| | modification | | | | | | |
| | (deg.) | | | | | | |
| | Al₂O₃ vapor | Co | S | S | S | A | S |
| | deposition | | | | | | |
| | inhibition | | | | | | |
| | properties | | | | | | |

TABLE 2

| | | | Example | Example | Example | Example | Example |
|---|---|---|---|---|---|---|---|
| Table 1 (continued) | | | A11 | A12 | A13 | A14 | A15 |
| Composition | Specific | Type | E-7 | E-7 | E-11 | E-1 | E-1 |
| | compound or | Amount | 0.05 | 0.05 | 0.05 | 5.00 | 0.001 |
| | comparative | (part by | | | | | |
| | compound | mass) | | | | | |
| | | Type | — | — | — | — | — |
| | | Amount | — | — | — | — | — |
| | | (part by | | | | | |
| | | mass) | | | | | |
| | | pKa | 2.4 | 2.4 | −0.6 | 1.8 | 1.8 |
| | Polymerization | Type | TEMPO | BHT | — | — | — |
| | inhibitor | Amount | 0.000005 | 0.000005 | — | — | — |
| | | (part by | | | | | |
| | | mass) | | | | | |
| | Solvent | Type | PGME | PGME | MIBC | PGME | PGME |
| | | Amount | Remainder | Remainder | Remainder | Remainder | Remainder |
| | | (part by | | | | | |
| | | mass) | | | | | |
| | Total (part by mass) | | 100 | 100 | 100 | 100 | 100 |
| Evaluation | Pure water | Co | 102 | 102 | 97 | 97 | 95 |
| | contact angle | Si | 20 | 20 | 22 | 50 | 21 |
| | after substrate | | | | | | |
| | modification | | | | | | |
| | (deg.) | | | | | | |
| | Al₂O₃ vapor | Co | S | S | S | S | A |
| | deposition | | | | | | |
| | inhibition | | | | | | |
| | properties | | | | | | |

| | | | | | Comparative | Comparative |
|---|---|---|---|---|---|---|
| | | | Example | Example | Example | Example |
| Table 1 (continued) | | | A16 | A17 | CA1 | CA2 |
| Composition | Specific | Type | E-1 | E-1 | — | CE-1 |
| | compound or | Amount | 0.01 | 0.01 | — | 0.10 |
| | comparative | (part by | | | | |
| | compound | mass) | | | | |
| | | Type | — | E-4 | — | — |
| | | Amount | — | 0.01 | — | — |
| | | (part by | | | | |
| | | mass) | | | | |
| | | pKa | 1.8 | 1.8 | — | 2.4 |
| | Polymerization | Type | — | — | — | — |
| | inhibitor | Amount | — | — | — | — |
| | | (part by | | | | |
| | | mass) | | | | |
| | Solvent | Type | PGME | PGME | PGME | PGME |
| | | Amount | Remainder | Remainder | Remainder | Remainder |
| | | (part by | | | | |
| | | mass) | | | | |
| | Total (part by mass) | | 100 | 100 | 100 | 100 |
| Evaluation | Pure water | Co | 97 | 97 | 50 | 104 |
| | contact angle | Si | 20 | 20 | 20 | 20 |
| | after substrate | | | | | |
| | modification | | | | | |
| | (deg.) | | | | | |
| | Al₂O₃ vapor | Co | S | S | E | E |
| | deposition | | | | | |
| | inhibition | | | | | |
| | properties | | | | | |

TABLE 3

| | | | Example | Example | Example | Example | Example | Example | Example | Example |
|---|---|---|---|---|---|---|---|---|---|---|
| Table 2 | | | B1 | B2 | B3 | B4 | B5 | B6 | B7 | B8 |
| Composition | Specific | Type | E-12 | E-13 | E-14 | E-15 | E-16 | E-17 | E-18 | E-19 |
| | compound or | Amount | 0.05 | 0.05 | 0.05 | 0.05 | 0.05 | 0.05 | 0.05 | 0.05 |
| | comparative | (part by | | | | | | | | |
| | compound | mass) | | | | | | | | |
| | | Type | — | — | — | — | — | — | — | — |
| | | Amount | — | — | — | — | — | — | — | — |
| | | (part by | | | | | | | | |
| | | mass) | | | | | | | | |
| | | pKa | 4.2 | 8.8 | 8.9 | 9.4 | 10.7 | 10.7 | 10.7 | 10.7 |
| | Polymerization | Type | — | — | — | — | — | — | — | TEMPO |
| | inhibitor | Amount | — | — | — | — | — | — | — | 0.000005 |
| | | (part by | | | | | | | | |
| | | mass) | | | | | | | | |
| | Solvent | Type | PGME | PGME | IPA | PGME | PGME | PGME | PGME | PGME |
| | | Amount | Remainder | Remainder | Remainder | Remainder | Remainder | Remainder | Remainder | Remainder |
| | | (part by mass) | | | | | | | | |
| | Total (part by mass) | | 100 | 100 | 100 | 100 | 100 | 100 | 100 | 100 |
| Evaluation | Pure water contact | W | 65 | 52 | 50 | 95 | 68 | 68 | 102 | 98 |
| | angle after | Si | 20 | 19 | 22 | 22 | 20 | 20 | 20 | 20 |
| | substrate | | | | | | | | | |
| | modification (deg.) | | | | | | | | | |
| | Al₂O₃ vapor | W | D | C | A | A | S | S | S | S |
| | deposition | | | | | | | | | |
| | inhibition | | | | | | | | | |
| | properties | | | | | | | | | |

| | | | | | | | Comparative | Comparative |
|---|---|---|---|---|---|---|---|---|
| | | | Example | Example | Example | Example | Example | Example |
| Table 2 | | | B9 | B10 | B11 | B12 | CB1 | CB2 |
| Composition | Specific | Type | E-20 | E-21 | E-16 | E-22 | — | CE-2 |
| | compound or | Amount | 0.05 | 0.05 | 0.01 | 0.03 | — | 0.10 |
| | comparative | (part by | | | | | | |
| | compound | mass) | | | | | | |
| | | Type | — | — | E-20 | — | — | — |
| | | Amount | — | — | 0.05 | — | — | — |
| | | (part by | | | | | | |
| | | mass) | | | | | | |
| | | pKa | 13.6 | 4.4 | — | 10.7 | — | 10.7 |
| | Polymerization | Type | — | — | — | — | — | — |
| | inhibitor | Amount | — | — | — | — | — | — |
| | | (part by | | | | | | |
| | | mass) | | | | | | |
| | Solvent | Type | PGME | PGME | PGME | PGME | PGME | PGME |
| | | Amount | Remainder | Remainder | Remainder | Remainder | Remainder | Remainder |
| | | (part by mass) | | | | | | |
| | Total (part by mass) | | 100 | 100 | 100 | 100 | 100 | 100 |
| Evaluation | Pure water contact | W | 98 | 100 | 100 | 92 | 27 | 100 |
| | angle after | Si | 22 | 21 | 20 | 20 | 20 | 20 |
| | substrate | | | | | | | |
| | modification (deg.) | | | | | | | |
| | Al₂O₃ vapor | W | B | B | S | S | E | E |
| | deposition | | | | | | | |
| | inhibition | | | | | | | |
| | properties | | | | | | | |

TABLE 4

| | | | Example | Example | Example | Example | Example |
|---|---|---|---|---|---|---|---|
| Table 3 | | | C1 | C2 | C3 | C4 | C5 |
| Composition | Specific | Type | E-7 | E-15 | E-16 | E-16 | E-18 |
| | compound or | Amount | 0.05 | 0.05 | 0.05 | 0.05 | 0.05 |
| | comparative | (part by | | | | | |
| | compound | mass) | | | | | |
| | | Type | — | — | — | — | — |
| | | Amount | — | — | — | — | — |
| | | (part by | | | | | |
| | | mass) | | | | | |
| | | pKa | 2.4 | 9.4 | 10.7 | 10.7 | 10.7 |
| | Polymerization | Type | BHT | — | — | — | — |
| | inhibitor | Amount | 0.000005 | — | — | — | — |
| | | (part by | | | | | |
| | | mass) | | | | | |
| | Solvent | Type | PGME | PGME | PGME | PGME/H₂O | PGME/H₂O |
| | | | | | | (7/3) | (9/1) |
| | | Amount | Remainder | Remainder | Remainder | Remainder | Remainder |
| | | (part by | | | | | |
| | | mass) | | | | | |
| | Total (part by mass) | | 100 | 100 | 100 | 100 | 100 |
| Evaluation | Pure water contact | Mo | 70 | 95 | 68 | 85 | 100 |
| | angle after substrate | Si | 20 | 19 | 22 | 22 | 20 |
| | modification (deg.) | | | | | | |
| | Al₂O₃ vapor | Mo | B | A | A | S | S |
| | deposition inhibition | | | | | | |
| | properties | | | | | | |

| | | | Example | Example | Example | Example |
|---|---|---|---|---|---|---|
| Table 3 | | | C6 | C7 | C8 | C9 |
| Composition | Specific | Type | E-23 | E-24 | E-25 | E-26 |
| | compound or | Amount | 0.05 | 0.05 | 0.05 | 0.05 |
| | comparative | (part by | | | | |
| | compound | mass) | | | | |
| | | Type | — | — | — | — |
| | | Amount | — | — | — | — |
| | | (part by | | | | |
| | | mass) | | | | |
| | | pKa | 10.7 | 10.7 | 10.7 | 10.7 |
| | Polymerization | Type | — | — | — | — |
| | inhibitor | Amount | — | — | — | — |
| | | (part by | | | | |
| | | mass) | | | | |
| | Solvent | Type | PGME/H₂O | PGME/H₂O | PGME/H₂O | PGME/H₂O |
| | | | (9/1) | (9/1) | (9/1) | (9/1) |
| | | Amount | Remainder | Remainder | Remainder | Remainder |
| | | (part by | | | | |
| | | mass) | | | | |
| | Total (part by mass) | | 100 | 100 | 100 | 100 |
| Evaluation | Pure water contact | Mo | 105 | 102 | 102 | 105 |
| | angle after substrate | Si | 20 | 20 | 20 | 22 |
| | modification (deg.) | | | | | |
| | Al₂O₃ vapor | Mo | S | S | S | S |
| | deposition inhibition | | | | | |
| | properties | | | | | |

As shown in Tables 1 to 3, it was found that the composition for treating a semiconductor device according to the embodiment of the present invention could form a coating film having excellent ALD inhibition properties.

From the comparison between Example A2 and Example A3 and the like, it was found that, in a case where the specific functional group of the specific compound was an acidic functional group and the acid dissociation constant of the compound when a proton was dissociated from the acidic functional group was 5.0 or less, the effect of the present invention was more excellent.

From the comparison between Example A2 and Example A3 and the like, it was found that, in a case where the specific functional group of the specific compound was an acidic functional group and the acidic functional group was a phosphonic acid group or a sulfo group, the effect of the present invention was more excellent.

From the comparison between Example A4 and Example A5 and the like, it was found that, in a case where the molecular weight of the specific compound was 200 or more, the effect of the present invention was more excellent.

From the comparison between Examples A5 to A9 and Examples B4 to B8 and the like, it was found that, in a case where the specific compound was the compound represented by General Formula (1) and satisfied at least one of the above-described requirement Y1 or the above-described requirement Y2, the effect of the present invention was more excellent.

From the comparison between Example B1 and Example B2 and the like, it was found that, in a case where the specific functional group of the specific compound was a basic functional group and the acid dissociation constant of the conjugate acid of the compound, obtained by adding a proton to the basic functional group, was 7.0 or more, the effect of the present invention was more excellent.

From the comparison between Examples B5 to B9 and the like, it was found that, in a case where the specific functional group of the specific compound was a basic functional group and the basic functional group was a primary amino group, the effect of the present invention was more excellent.

From the comparison between Examples C1 to C3 and the like, it was found that, in a case where the specific functional group included in the specific compound was a basic functional group, the ALD inhibition properties with respect to a molybdenum surface in a case where the substrate had the molybdenum surface were more excellent.

From the comparison between Examples C3 to C9 and the like, it was found that, in a case where the composition for treating a semiconductor device according to the embodiment of the present invention contained an organic solvent and water, the effect of the present invention was more excellent.

What is claimed is:

1. A composition for treating a semiconductor device, comprising:
a compound which has a specific functional group bonded or adsorbed to a substrate and has a carbon-carbon triple bond; and
a solvent,
wherein the specific functional group is a basic functional group or an acidic functional group.

2. The composition for treating a semiconductor device according to claim 1,
wherein, in a case where the specific functional group is the basic functional group, an acid dissociation constant of a conjugate acid of the compound, which is obtained by adding a proton to the basic functional group, is 7.0 or more, and
in a case where the specific functional group is the acidic functional group, an acid dissociation constant of the compound when a proton is dissociated from the acidic functional group is 5.0 or less.

3. The composition for treating a semiconductor device according to claim 1,
wherein the basic functional group is an amino group, a hydrazine group, or a guanidine group.

4. The composition for treating a semiconductor device according to claim 3,
wherein the basic functional group is a primary amino group, a secondary amino group, or a tertiary amino group.

5. The composition for treating a semiconductor device according to claim 4,
wherein the basic functional group is a primary amino group.

6. The composition for treating a semiconductor device according to claim 1,
wherein the acidic functional group is a phosphonic acid group, a sulfo group, or a carboxy group.

7. The composition for treating a semiconductor device according to claim 6,
wherein the acidic functional group is a phosphonic acid group or a sulfo group.

8. The composition for treating a semiconductor device according to claim 1,
wherein a molecular weight of the compound is 200 or more.

9. The composition for treating a semiconductor device according to claim 1,
wherein the compound is a compound represented by General Formula (1), 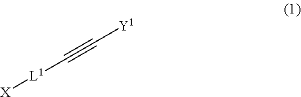
in General Formula (1),
X represents a primary amino group, a phosphonic acid group, or a sulfo group,
L¹ represents a single bond or a divalent linking group, and
Y¹ represents an aliphatic hydrocarbon group which may have a substituent, an aromatic group which may have a substituent, or a hydrogen atom.

10. The composition for treating a semiconductor device according to claim 9,
wherein a molecular weight of the compound represented by General Formula (1) is 200 or more.

11. The composition for treating a semiconductor device according to claim 9,
wherein the compound represented by General Formula (1) satisfies at least one of a requirement X1 or a requirement X2,
the requirement X1: L¹ is a divalent linking group including a divalent aliphatic hydrocarbon group having 6 or more carbon atoms,
the requirement X2: Y¹ is an aliphatic hydrocarbon group having 6 or more carbon atoms, which may have a substituent.

12. The composition for treating a semiconductor device according to claim 9,
wherein the compound represented by General Formula (1) satisfies at least one of a requirement Y1 or a requirement Y2,
the requirement Y1: L¹ is a divalent linking group including a divalent aromatic group which may have a substituent,
the requirement Y2: Y¹ is an aromatic group which may have a substituent.

13. The composition for treating a semiconductor device according to claim 9,
wherein the compound represented by General Formula (1) is a compound represented by General Formula (1b), 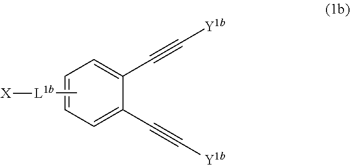
in General Formula (1b),
X represents a primary amino group, a phosphonic acid group, or a sulfo group,
L^{1b} represents a single bond or a divalent linking group, and
Y^{1b}'s each independently represent a hydrogen atom, an aliphatic hydrocarbon group which may have a substituent, or an aromatic group which may have a substituent.

14. The composition for treating a semiconductor device according to claim 1,
wherein a content of the compound is 5.00% by mass or less with respect to a total mass of the composition for treating a semiconductor device.

15. The composition for treating a semiconductor device according to claim 1,
wherein the solvent includes an organic solvent and water.

16. The composition for treating a semiconductor device according to claim 1,
wherein a total amount of the compound and the solvent is 99.90% by mass or more with respect to a total mass of the composition for treating a semiconductor device.

17. The composition for treating a semiconductor device according to claim 1,
wherein a water contact angle of a film obtained by applying the composition for treating a semiconductor device is 60 degrees or more.

18. A manufacturing method of a modified substrate, comprising:
a step of bringing a substrate into contact with the composition for treating a semiconductor device according to claim 1; and
a step of performing a heating treatment on the substrate in contact with the composition to form a coating film on the substrate.

19. A manufacturing method of a laminate, comprising:
a step 1 of bringing a substrate having at least two types of surfaces of a first surface and a second surface, each surface being composed of a different material, into contact with the composition for treating a semiconductor device according to claim 1 to form a first coating film on the first surface; and
a step 2 of performing an atomic layer deposition treatment on the substrate obtained in the step 1 to form a second coating film on the second surface.

20. A manufacturing method of an electronic device, comprising:
the manufacturing method of a modified substrate according to claim 18.

21. A compound represented by General Formula (2), 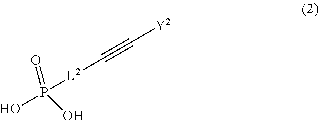
in General Formula (2),
L² represents a divalent linking group including a divalent aromatic group, and
Y² represents an aliphatic hydrocarbon group having 8 or more carbon atoms, which may have a substituent, or an aromatic group which may have a substituent.

22. A compound represented by General Formula (3), 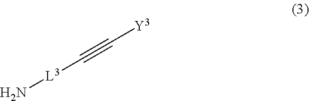
in General Formula (3),
L³ represents a divalent linking group including a divalent aromatic group, and
Y³ represents an aliphatic hydrocarbon group having 8 or more carbon atoms, which may have a substituent, or an aromatic group which may have a substituent.
